(19) United States
(12) Patent Application Publication
(10) Pub. No.: US 2021/0086208 A1
(43) Pub. Date: Mar. 25, 2021

(54) Manufacturing System for a Nano-Scale Energy Harvesting Device

(71) Applicant: Birmingham Technologies, Inc., Arlington, VA (US)

(72) Inventors: Joseph Birmingham, Arlington, VA (US); James P. Brainard, Pocatello, ID (US)

(73) Assignee: Birmingham Technologies, Inc., Arlington, VA (US)

(21) Appl. No.: 16/582,541

(22) Filed: Sep. 25, 2019

(51) Int. Cl. B05B 5/08; B05B 5/00

(52) U.S. Cl. CPC B05B 5/082; H01L 35/32; B05B 5/001

(57) ABSTRACT

Embodiments relate to a system for manufacturing nano-scale energy harvesters and electric power generators. The system includes a plurality of dispensers to dispense a first material, a second material, and a separation material between the first and second materials. The first material has a first work function value and the second material has a second work function value different from the first work function value. At least one electrospray device is positioned proximal to the third dispenser to deposit a fluid within at least a portion of the separation material. The fluid has particles with a third work function value different from the first and second work function values. The system also includes a guide assembly to transport the first and second electrodes, the positioned separation material, and the fluid to a joint proximal position and form a fabricated product.

### BACKGROUND

The present embodiments relate to manufacturing devices directed toward electric power generation, energy conversion, and energy transfer. More specifically, the embodiments disclosed herein are related to manufacturing systems for nano-scale energy harvesting devices that generate electric power through thermionic energy conversion and thermoelectric energy conversion.

### SUMMARY

The embodiments described herein are directed to a system, and in one embodiment one or more variations of the system and system components, to manufacture nano-scale energy harvesting devices.

In one aspect, the system is provided with a first dispenser, a second dispenser, and a third dispenser. The first dispenser dispenses a first material having a first work function value. The second dispenser dispenses a second material having a second work function value different from the first work function value. The third dispenser deposits a separation material between the first and second materials. The system also includes at least one device positioned proximal to the third dispense and configured to deposit a fluid within at least a portion of the separation material. The fluid has a third work function value different from the first and second work function values. The system further includes a guide assembly operably coupled to the first, second, and third dispensers. The guide assembly transports the first and second electrodes, the positioned separation material, and the fluid to a joint proximal position to form a fabricated product.

In another aspect, the system is provided with a first dispenser and a second dispenser. The first dispenser dispenses a first component. The first component includes a first electrode and a separation material positioned in at least partial communication with the first electrode. The first electrode has a first work function value. The second dispenser dispenses a second component. The second component includes a second electrode. The second electrode has a second work function value different from the first work function value. The system also includes at least one device positioned proximal to the first dispenser. The device deposits a fluid within at least a portion of the separation material. At least a portion of the fluid has a third work function value different from the first and second work function values. The system further includes a guide assembly operably coupled to the first and second dispensers. The guide assembly transports the first and second components to a joint proximal position to form a fabricated product including the first and second components and the fluid.

In yet another aspect, the system is provided with a first dispenser, a second dispenser, and a third dispenser. The first dispenser dispenses a first material having a first work function value. The second dispenser dispenses a second material having a second work function value different from the first work function value. The system also includes a first electrospray device and a second electrospray device. The first electrospray device is positioned proximal to the first dispenser. The first electrospray device deposits at least one first electrospray material over at least a portion of the first material to fabricate a first electrode material having a third work function value. The second electrospray device is positioned proximal to the second dispenser. The second electrospray device deposits at least one second electrospray material over at least a portion of the second material to fabricate a second electrode material having a fourth work function value. The system further includes a guide assembly operably coupled to the first and second dispensers. The guide assembly transports the first and second electrode materials to a joint proximal position. The guide assembly positions an opening between the first and second electrode materials. The third dispenser deposits a separation material into the opening. The system fabricates a product including the first and second electrode materials and the positioned separation material.

These and other features and advantages will become apparent from the following detailed description of the presently preferred embodiment(s), taken in conjunction with the accompanying drawings.

### BRIEF DESCRIPTION OF THE SEVERAL VIEWS OF THE DRAWINGS

The drawings referenced herein form a part of the specification. Features shown in the drawings are meant as illustrative of only some embodiments, and not of all embodiments, unless otherwise explicitly indicated.

FIG. 1 depicts a sectional view of one embodiment of a nano-scale energy harvesting device.

FIG. 2A depicts a top view of one embodiment of a spacer and adjacent electrodes for use in a nano-scale energy device.

FIG. 2B depicts a top view of one embodiment of a spacer and adjacent electrodes for use in a nano-scale energy device.

FIG. 3 depicts a schematic view of one embodiment of a nano-fluid including a plurality of nano-particle clusters suspended in a dielectric medium.

FIG. 4 depicts a schematic view of one embodiment of a manufacturing system for nano-scale energy harvesting devices.

FIG. 5 depicts an enlarged schematic view of a portion of the manufacturing system.

FIG. 6 depicts a schematic perspective view of an arcuate electric power harvesting device.

FIG. 7 depicts a perspective view of an arcuate electric power harvesting device.

FIG. 8 depicts a schematic perspective view of a planar electric power harvesting device.

FIG. 9 depicts a perspective view of a first repository of layered materials that may be used to manufacture the electric power harvesting device(s).

FIG. 10 depicts a perspective view of a second repository of layered materials that may be used to manufacture the electric power harvesting device(s).

FIG. 11 depicts a flow diagram of one embodiment of a system to manufacture electric power generation modules with the device(s) described herein.

FIG. 12 depicts a schematic view of one embodiment of a manufacturing system for nano-scale energy harvesting device(s).

### DETAILED DESCRIPTION

It will be readily understood that the components of the present embodiments, as generally described and illustrated in the Figures herein, may be arranged and designed in a wide variety of different configurations. Thus, the following detailed description of the embodiments of the apparatus, system, and method of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Thermoelectric power conversion presents an avenue to harvest and convert thermal energy into electricity. Thermoelectric power generation requires the attachment of one electrode to a different electrode to form a junction therebetween where the two electrodes experience a temperature gradient. Based on the Seebeck effect, the temperature gradient induces a voltage. Higher temperature differentials tend to produce higher voltages and electric currents. However, due to the transfer of heat between the two materials at the junction, a thermal backflow is introduced which reduces the efficiency of thermoelectric power conversion systems.

Thermionic power conversion presents an avenue to convert thermal energy into electrical energy. Thermoelectric power conversion generators convert thermal energy to electrical energy by emission of electrons from a heated emitter electrode (i.e., a cathode). Electrons flow from an emitter electrode, across an inter-electrode gap, to a collector electrode (i.e., an anode), through an external load, and return back to the emitter electrode, thereby converting heat to electrical energy. Recent improvements in thermionic power converters pertain to material selection based on work functions and corresponding work function values for the electrodes and using a fluid to fill the inter-electrode gap. Electron transfer density is limited by the materials of the electrodes and the materials of the fluid in the inter-electrode gap (i.e., the associated work functions).

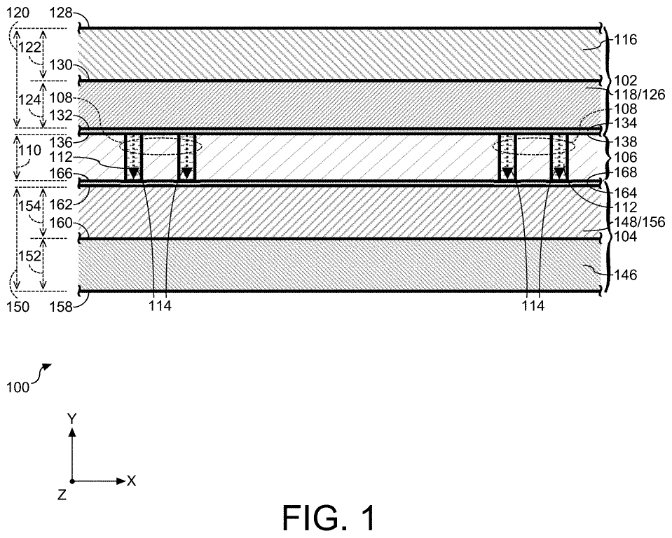

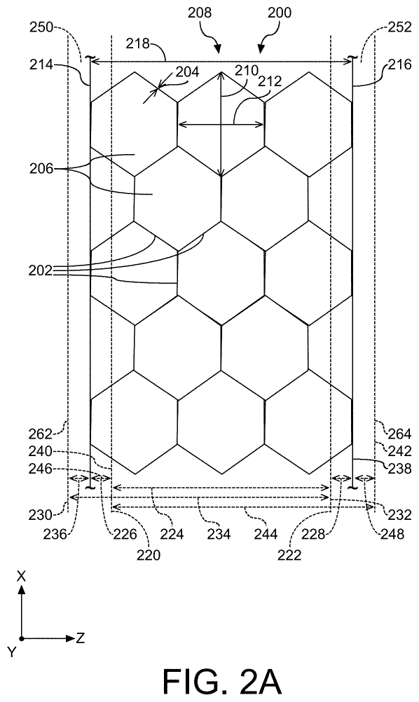

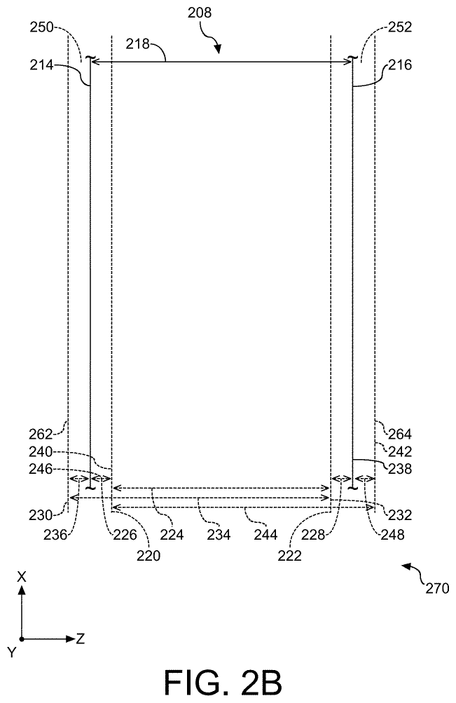

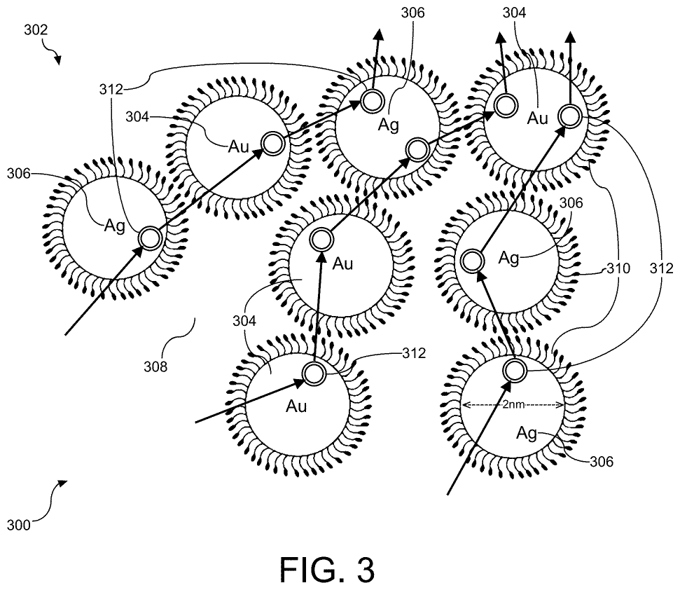

To provide additional details for an improved understanding of selected embodiments of the present disclosure that combine the use of thermoelectric and thermionic power conversion, reference is now made FIG. 1 illustrating a sectional view of one embodiment of a nano-scale energy harvesting device (100) that is configured to generate electrical power. Each of the dimensions, including a thickness dimension defined parallel to a first-axis, also referred to herein as a vertical axis, e.g. Y-axis, a longitudinal dimension parallel to a second-axis, e.g. X-axis, also referred to herein as a horizontal axis, and a lateral dimension parallel to a third axis-axis, e.g. Z-axis, orthogonal to the first-axis and second axis, are shown for reference. The X-axis, Y-axis, and Z-axis are orthogonal to each other in physical space. In one embodiment, the nano-scale energy harvesting device (100) is referred to as a cell. In one embodiment, the nano-scale energy harvesting device (100) is referred to as a layer. A plurality of devices (100) may be organized as a plurality of cells, or in one embodiment a plurality of layers, with the cells or layers arranged in series or parallel, or a combination of both to generate electrical power at the desired voltage, current, and power output. The nano-scale energy harvesting device (100) includes an emitter electrode (cathode) (102) and a collector electrode (anode) (104) positioned to define an opening (140) therebetween. In one embodiment, a spacer (106) of separation material, sometimes referred to herein as a standoff or spacer, maintains separation between the electrodes (102) and (104). In one embodiment, the spacer (106) is an insulator or comprises non-conductive properties. The spacer (106) is in direct contact with the electrodes (102) and (104). The electrodes (102) and (104) and the spacer (106) define a plurality of apertures (108), also referred to herein as cavities, (discussed further below with respect to FIGS. 2A and 2B). The apertures (108) extend between the electrodes (102) and (104) for a distance (110) in the range from about 1 nanometer (nm) to about 100 nm, and in one embodiment, the distance (110) ranges from about 1 nm to about 20 nm. A fluid (112), also referred to herein as a nano-fluid, (discussed further herein with reference to FIG. 3) is received and maintained within each aperture (108). In one embodiment, no spacer (106) is used and only the nano-fluid (112) is positioned between the electrodes (102) and (104). Accordingly, the nano-scale energy harvesting device (100) includes two opposing electrodes (102) and (104), optionally separated the spacer (106), with a plurality of apertures (108) extending between the electrodes (102) and (104) and configured to receive the (112).

The emitter electrode (102) and the collector electrode (104) are each fabricated with different materials, with the different materials having separate and different work function values. As used herein, the work function of a material, or in one embodiment a combination of materials, is the minimum thermodynamic work, i.e., minimum energy, needed to remove an electron from a solid to a point in a vacuum immediately outside a solid surface of the material. The work function is a material-dependent characteristic. Work function values are typically expressed in units of electron volts (eV). Accordingly, the work function of a material determines the minimum energy required for electrons to escape the surface, with lower work functions generally facilitating electron emission.

The emitter electrode (102) has a higher work function value than the collector electrode (104). The difference in work function values between the electrodes (102) and (104) due to the different electrode materials induces a contact potential difference between the electrodes (102) and (104) that has to be overcome to transmit electrons through the fluid (112) within the apertures (108) from the emitter electrode (102) to the collector electrode (104). Both electrodes (102) and (104) emit electrons, however, as explained in more detail elsewhere herein, once the contact potential difference is overcome, the emitter electrode (102) will emit significantly more electrons than the collector electrode (104). A net flow of electrons will be transferred from the emitter electrode (102) to the collector electrode (104), and a net electric current (114) will flow from the emitter electrode (102) to the collector electrode (104) through the apertures (108). This net current (114) causes the emitter electrode (102) to become positively charged and the collector electrode (104) to become negatively charged. Accordingly, the nano-scale energy harvesting device (100) generates an electrical current (114) that is transmitted from the emitter electrode (102) to the collector electrode (104).

The emitter electrode (102) is manufactured with a first backing (116), which in one embodiment is comprised of polyester film, e.g., Mylar®, and a first layer (118) extending over the first backing (116). In one embodiment, the first layer (118) is comprised of aluminum (Al). The emitter electrode (120) has an emitter electrode measurement (120) that in one embodiment is approximately 0.25 millimeters (mm), such measurement being non-limiting, and in one embodiment may have a measurement from about 2 nm to about 0.25 mm. The first backing (116) is shown herein with a first backing measurement, (122), and the first layer (118) is shown herein with a first layer measurement (124). In one embodiment, the first backing measurement (122) and the first layer measurement (124) range from about 0.01 mm to about 0.125 mm, and in one embodiment are each approximately 0.125 mm, such values being non-limiting. In one embodiment, the first backing measurement (122) and the first layer measurement (124) may have different measurement values. In one embodiment, the first layer (118) is sprayed on to the first backing (116) to form a nano-particle layer (126) that is approximately 2 nm (i.e., the approximate length of a nano-particle), where the 2 nm value should be considered non-limiting. In one embodiment, the first layer (118) may range from approximately 1 nm to about 20 nm. The first backing (116) has an outer surface (128) and the first backing (116) and the first layer (118) or the nano-particle layer (126) define a first interface (130). The first layer (118) and the nano-particle layer (126) define a first surface (132). A first coating (134), which in one embodiment is comprised of cesium oxide (Cs₂O) and discussed further herein, at least partially covers the first surface (132) to form an emitter surface (136) that directly interfaces with a first spacer surface (138). Accordingly, the emitter electrode (102) is manufactured with a first layer (118) or nano-particle layer (126) on a first backing (116) and the first coating (134) on the first surface (132).

The collector electrode (104) is manufactured with a second backing (146), which in one embodiment is comprised of a polyester film, and at least one layer (148), which in one embodiment is comprised of platinum (Pt), extending over the second backing (146). The collector electrode has a collector electrode measurement (150) that in one embodiment is approximately 0.25 millimeters (mm), such measurement being non-limiting, and in one embodiment may have a measurement from about 2 nm to about 0.25 mm. In one embodiment, a second backing measurement (152) of the second backing (146) and a second layer measurement (154) of the layer (148) are each approximately 0.125 mm, such values being non-limiting. In one embodiment, the second backing measurement (152) and the second layer measurement (154) range from about 0.01 mm to about 0.125 mm, and in one embodiment are each approximately 0.125 mm, such values being non-limiting. In one embodiment, the first backing measurement (152) and the first layer measurement (154) may have different measurement values. In one embodiment, the layer (148) is sprayed on to the second backing (146) to form a nano-particle layer (156) that is approximately 2 nm, where the 2 nm value should be considered non-limiting. In one embodiment, the layer (148) may range from approximately 1 nm to about 20 nm. The second backing (146) has an outer surface (158) and the second backing (146) and the nano-particle layer (156) define a second interface (160). The layer (148) and the nano-particle layer (156) define a second surface (162). A second coating (164), which in one embodiment is comprised of cesium oxide (Cs₂O) and discussed further herein, at least partially covers the second surface (162) to form a collector surface (166) that directly interfaces with a second surface (168) of the spacer (106). Accordingly, a collector electrode (104) is manufactured with the nano-particle layer (156) on the second backing (146) and a Cs₂O coating (164) on the surface (162).

The first and second coatings, (134) and (164) respectively, are formed on the first and second surfaces (132) and (162), respectively. In one embodiment, an electrospray or nano-fabrication techniques, with one or more predetermined patterns, is employed to form or apply the first and second coatings, (134) and (164), respectively. In one embodiment, the first surface (132) is referred to as an Aluminum surface and the second surface (162) is referred to as a Platinum surface. A percentage of coverage of each of the first surface (132) and second surface (162) with the respective Cs₂O coating layers (134) and (164) is within a range of at least 50% and up to 70%, and in at least one embodiment, is about 60%. The Cs₂O coatings (134) and (164) reduce the work function values of the electrodes (102) and (104) from the work function values of Aluminum, which in one embodiment is 4.28 electron volts (eV), and Platinum, which is one embodiment is 5.65 eV. The emitter electrode (102) with the Cs₂O coating layer has a work function value ranging from about 0.5 to about 2.0 eV, and in one embodiment is approximately 1.5 eV, and the collector electrode (104) with the Cs₂O coating layer has a work function value of about 0.5 to about 2.0 eV, and in one embodiment is approximately 1.5 eV. In one embodiment, the surface area coverage on the emitter electrode (102) or the collector electrode (104) of Cs₂O is spatially resolved, e.g. applied in a pattern or non-uniform across the length of the corresponding surface, and provides a reduction in a corresponding work function to a minimum value. In one embodiment, the work function value, from a maximum of about 2.0 eV is reduced approximately 60-80% corresponding to the surface coverage of the Cs₂O, e.g. Cesium atoms. Accordingly, the work function values of the electrodes (102) and (104) are essential to the operation of the nano-scale energy harvesting device (100) as described herein.

Aluminum (Al) and Platinum (Pt) materials are selected for the electrodes (102) and (104), respectively, due to at least some of their metallic properties, e.g., strength and resistance to corrosion, and the measured change in work function when the thermionic emissive material of Cs₂O is layered thereon. Alternative materials may be used, such as noble metals including, and without limitation, rhenium (Re), osmium (Os), ruthenium (Ru), tantalum (Ta), iridium (Jr), rhodium (Rh), and palladium (Pd), or any combination of these metals. In addition, and without limitation, non-noble metals such as gold (Au), tungsten (W), and molybdenum (Mo) may also be used. For example, and without limitation, W nano-particles may be used rather than Al nano-particles to form surface (132), and Au nano-particles may be used rather than Pt nano-particles to form surface (162). Accordingly, the selection of the materials to use to form the nano-particle surfaces (132) and (162) is principally based on the work functions of the electrodes (102) and (104) and more specifically, the difference in the work functions once the electrodes (102) and (104) are fully fabricated.

The selection of the coatings, e.g. thermionic electron emissive material (134) and (164), to deposit on the respective first surface (132) and second surface (162) is partially based on the desired work function value of the electrodes (102) and (104), respectively, and chemical compatibility between the deposited materials, and the deposited thermionic electron emissive materials (134) and (164). Deposition materials include, but are not limited to, thorium, aluminum, cerium, and scandium, as well as oxides of alkali or alkaline earth metals, such as cesium, barium, calcium, and strontium. In at least one embodiment, the thickness of the layer of patterned thermionic electron emissive material (134) and (164) is approximately 2 nm, where the 2 nm value should be considered non-limiting. Accordingly, the electrodes (102) and (104) have the desired work functions.

FIG. 2A depicts a top view of one embodiment of a spacer (200) and the adjacent electrodes (262) and (264) for use in the nano-scale energy device, as shown and described in FIG. 1. The spacer (200) and electrodes (262) and (264) are not shown to scale. Electrodes (262) and (264) are shown in phantom. The spacer (200), as shown and described herein, includes a plurality of interconnected edges (202). The edges (202) have a thickness or edge measurement (204) in the range of about 2.0 nm to about 0.25 mm. As shown herein, the edges (202) are interconnected. In one embodiment, the interconnected edges (202) define a plurality of hexagonal apertures, also referred to herein as cavities, (206), in an array (208). In one embodiment, the spacer (200) may be configured as a uniform or relatively uniform layer, e.g. contiguous and with or without limited apertures. Referring to FIG. 2B, a top view of one embodiment of a spacer (270) and the adjacent electrodes (262) and (264) is shown for use in the nano-scale energy device, as shown and described in FIG. 1. The embodiment shown and described in FIG. 2B is provided with similar numbers as that shown in FIG. 2A. The spacer (270) may be comprised of a permeable or semi-permeable material, which in one embodiment may be adapted to receive or be coated or impregnated with the nanofluid. The apertures or cavities, either uniformly or non-uniformly provided across the width and/or length of the spacer material, ranging from about 0 to about 0.25 mm. Referring to FIG. 2A, in one embodiment, the apertures (206) have a first dimension (210) and a second dimension (212) each having a value in a range between 2.0 nm and 100 microns. In one embodiment, the edges (202), apertures (206), and array (208) may form various shapes, configurations, and sizes, including the dimensions and sizing of the apertures (206), that enable operation of spacer (200) as described herein, including, without limitation, circular, rectangular, and elliptical apertures (206).

The spacers (200) and (270), shown in FIGS. 2A and 2B, respectively, also includes first and second edges (214) and (216), respectively, that define the dimensions, e.g. outer edges, of the spacer (200). The spacer (200) has a distance measure (218) in the lateral dimension (Z) between the lateral side edges (214) and (216). In one embodiment, the distance measure (218) has a range between about 1 nm to approximately 10 microns. In one embodiment, from the perspective of the top view as shown, the emitter electrode (262) and the collector electrode (264) each have lateral side edges (220) and (222) (shown in phantom) that are separated by a distance or opening (224), referred to herein as a first distance. In one embodiment, the distance or opening (224) has a size extending from about 1.1 nm to about 10 microns. In one embodiment, a second distance (226) is defined between the lateral edge (214) and the lateral side edge (220) in the lateral dimension, Z. Similarly, a third distance (228) is defined between the lateral support side edge (216) and the lateral side edge (222). In one embodiment, the second and third distance values (226) and (228), respectively, are within a range of approximately 1.1 nm to approximately 10 microns. In one embodiment, the second and third distance values (226) and (228), respectively, are approximately the same. In one embodiment, the second and third distance values (226) and (228), respectively, are different. In one embodiment, the distance measure (218), and the first, second, and third distance values (224), (226), and (228), respectively, have any values that enable operation of the nano-scale energy harvesting device (100) as described herein. In one embodiment, the spacer (200) has a lateral measurement (218) with respect to the Z-axis greater than the lateral measurements (224) of the electrodes (262) and (264). The spacer measurements shown and described herein reduce a potential for the electrode (102) contacting the electrode (104), which would create a short circuit.

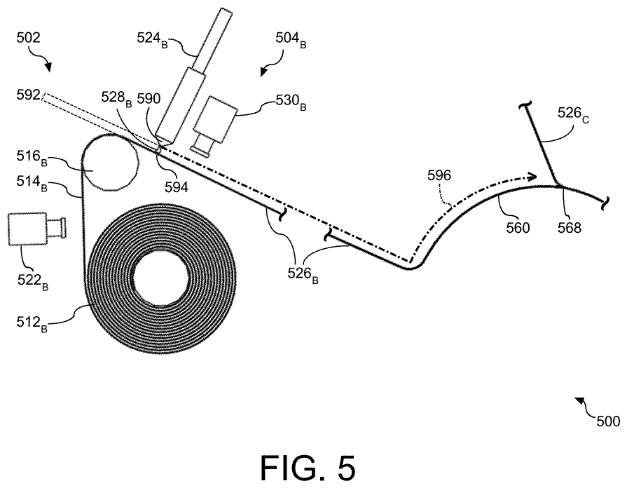

As shown in FIGS. 2A and 2B, the electrodes (262) and (264) are offset in an opposing manner in the lateral dimension, Z, with respect to the spacer (200). Specifically, for the electrode (262), lateral side edges (230) and (232) (shown in phantom) of the electrode (262) are separated by a lateral distance (234). In one embodiment, lateral distance value (234) is within a range of approximately 10 mm to approximately 2.0 m. Therefore, the lateral side edge (230) extends a distance (236) beyond the lateral support side edge (214) and the lateral support side edge (216) extends a distance (238) beyond the lateral side edge (232). Similarly, for the electrode (264), the lateral side edges (240) and (242) (shown in phantom) of the electrode (264) are separated by a lateral distance (244). In one embodiment, the lateral distance (244) is within a range of approximately 10 mm to approximately 2.0 m. Therefore, the lateral support side edge (214) extends a distance (246) beyond the lateral side edge (240) and the lateral side edge (242) extends a distance (248) beyond the lateral support side edge (216). In one embodiment, distance values (236), (238), (246), and (248) are within a range of approximately 1 nm to approximately 10 microns. In one embodiment, distance values (236), (238), (246), and (248) are approximately the same. In one embodiment, distance values (236), (238), (246), and (248) are different. In one embodiment, distances (236), (238), (246), and (248) have any values that enable operation of the nano-scale energy harvesting device (100) as described herein. Each of the lateral support side edges (214) and (216) receive at least one layer of an electrically insulative sealant, as shown and described in detail in FIG. 5, that electrically isolates the portions (250) and (252) of the electrodes (262) and (264), respectively, that extend beyond the lateral support side edges (214) and (216), respectively. Accordingly, each of the electrodes (262) and (264) are offset from the spacer (200) to reduce the potential for the electrodes (262) and (264) contacting each other and creating a short circuit therebetween.

The spacers (200) and (270), also referred to herein as dielectric spacers, as shown and described in FIGS. 2A and 2B, respectively, are fabricated with a dielectric material, such as, and without limitation, silica (silicon dioxide), alumina (aluminum oxide), and titania (titanium dioxide). The apertures (206) extend between the electrodes (262) and 264) for the distance (110), e.g. in the Y-dimension, in a range from about 1 nanometer (nm) to about 10 microns. A fluid (112), e.g. nano-fluid, as shown and described in detail in FIG. 3, is received and maintained within each aperture (206). The dielectric spacer (200) is positioned between, and in direct contact with, the electrodes (262) and (264).

Referring to FIG. 3, a diagram (300) is provided to illustrate a schematic view of one embodiment of a fluid (302), also referred to herein as a nano-fluid. As shown, the nano-fluid (302) includes a plurality of gold (Au) clusters (304) and a plurality of silver (Ag) nano-particle clusters (306), respectively, suspended in a dielectric medium (308). In some embodiments, and without limitation, the dielectric medium (308) is selected from one of the groups including alcohols, ketones (e.g., acetone), ethers, glycols, olefins, and alkanes (i.e., those alkanes with greater than three carbon atoms, e.g., tetradecane). In one embodiment, the dielectric medium (308) is one of water and silicone oil. Also, in at least one embodiment, the dielectric medium (308) is a sol-gel with aerogel-like properties and low thermal conductivity values that reduce heat transfer therethrough, e.g., thermal conductivity values as low as 0.013 watts per meter-degrees Kelvin (W/m-° K) as compared to the thermal conductivity of water at 20 degrees Celsius (° C.) of 0.6 W/m-° K. Appropriate materials are selected prior to fabricating the nano-particle clusters (304) and (306). The principle requirement for material selection of the nano-particle clusters (304) and (306) is that the materials must have work function values that are greater than the work function values for the electrodes (102) and (104). Specifically, the work function values of the Au nano-particle clusters (304) and the Ag nano-particle clusters (306) are about 4.1 eV and 3.8 eV, respectively.

At least one layer of a dielectric coating, such as a monolayer of alkanethiol material (310), is deposited on the Au and Ag nano-particle clusters (304) and (306), respectively, to form a dielectric barrier thereon. In one embodiment, the deposit of the dielectric coating is through electrospray. The alkanethiol material (310) includes, but is not limited to dodecanethiol and decanethiol. The deposit of the dielectric coating, such as alkanethiol, reduces coalescence of the nano-particle clusters (304) and (306). In at least one embodiment, the nano-particle clusters (304) and (306) have a diameter in the range of about 1 nm to about 3 nm. In one embodiment, the nano-particle clusters (304) and (306) have a diameter of about 2 nm. The nano-particle clusters of Au (304) and Ag (306) are tailored to be electrically conductive with charge storage features (i.e., capacitive features), minimize heat transfer through the spacer apertures (206) with low thermal conductivity values, minimize ohmic heating, eliminate space charges in the spacer apertures (206), and prevent arcing. The plurality of Au and Ag nano-particle clusters (304) and (306), respectively, are suspended in the dielectric medium (308). The nano-fluid (302), including the suspended nano-particle clusters (304) and (306), provides a conductive pathway for electrons to travel across the spacer apertures (206) from the emitter electrode (102) to the collector electrode (104) through charge transfer. Accordingly, in at least one embodiment, a plurality of Au and Ag nano-particle clusters (304) and (306) are mixed together in a dielectric medium (308) to form a nano-fluid (302), the nano-fluid (302) residing in the apertures (108) and (206).

Thermally-induced Brownian motion causes the nano-particle clusters (304) and (306) to move within the dielectric medium (308), and during this movement they occasionally collide with each other and with the electrodes (102) and (104). As the nano-particle clusters (304) and (306) move and collide within the dielectric medium (308), the nano-particle clusters (304) and (306) chemically and physically transfer charge. The nano-particle clusters (304) and (306) transfer charge chemically when electrons (312) hop from the electrodes (102) and (104) to the nano-particle clusters (304) and (306) and from one nano-particle cluster (304) and (306) to another nano-particle cluster. The hops primarily occur during collisions. Due to differences in work function values, electrons (312) are more likely to move from the emitter electrode (102) to the collector electrode (104) via the nano-particle clusters (304) and (306) rather than in the reverse direction. Accordingly, a net electron current from the emitter electrode (102) to the collector electrode (104) via the nano-particle clusters (304) and (306) is the primary and dominant current of the nano-scale energy harvesting device (100).

The nano-particle clusters (304) and (306) transfer charge physically (i.e., undergo transient charging) due to the ionization of the nano-particle clusters (304) and (306) upon receipt of an electron, and the electric field generated by the differently charged electrodes (102) and (104). The nano-particle clusters (304) and (306) become ionized in collisions when they gain or lose an electron (312). Positive and negative charged nano-particle clusters (304) and (306) in the nano-fluid (302) migrate to the negatively charged collector electrode (104) and the positively charged emitter electrode (102), respectively, providing a current flow. This ion current flow is in the opposite direction from the electron current flow, but less in magnitude than the electron flow.

When the emitter electrode (102) and the collector electrode (104) are initially brought into close proximity, the electrons of the collector electrode (104) have a higher Fermi level than the electrons of the emitter electrode (102) due to the lower work function of the collector electrode (104). The difference in Fermi levels drives a net electron current that transfers electrons from the collector electrode (104) to the emitter electrode (102) until the Fermi levels are equal, i.e., the electrochemical potentials are balanced and thermodynamic equilibrium is achieved. The transfer of electrons between the emitter electrode (102) and the collector electrode (104) results in a difference in charge between the emitter electrode (102) and the collector electrode (104). This charge difference sets up the voltage of the contact potential difference and an electric field between the emitter electrode (102) and the collector electrode (104), where the polarity of the contact potential difference is determined by the material having the greatest work function. With the Fermi levels equalized, no net current will flow between the emitter electrode (102) and the collector electrode (104). Accordingly, electrically coupling the emitter electrode (102) and the collector electrode (104) with no external load results in attaining the contact potential difference between the electrodes (102) and (104) and no net current flow between the electrodes (102) and (104) due to attainment of thermodynamic equilibrium between the two electrodes (102) and (104).

As described this far, the principle electron transfer mechanism for operation of the nano-scale energy harvesting device (100) is thermionic energy conversion or harvesting. In some embodiments, thermoelectric energy conversion is conducted in parallel with the thermionic energy conversion. In at least one of such embodiments, either the emitter electrode (102) or the collector electrode (104), or both, include a material in the form of lead selenide telluride (PbSeTe) or lead telluride (PbTe). PbSeTe and PbTe are thermoelectric conversion materials that, when introduced into the emitter electrode (102) during fabrication, allows for emission of electrons from the emitter electrode (102) through thermoelectric electron emission. In some embodiments, the PbSeTe or PbTe is also introduced into the collector electrode (104) during fabrication. Similarly, in some embodiments, the PbSeTe or PbTe is introduced during fabrication into at least a portion of the suspended nano-particle clusters (304) and (306). Accordingly, the use of the PbSeTe or PbTe as described herein increases conversion of thermal energy to electrical energy through further increasing the rate of transfer of electrons through the nano-scale energy harvesting device (100).

Furthermore, the PbSeTe or PbTe used as described herein may be an n-type compound doped with a transition metal in the form of bismuth (Bi) or antimony (Sb). The doping of the n-type compound of PbSeTe or PbTe with the transition metal further increases conversion of thermal energy to electrical energy through further increasing the rate of transfer of electrons through the nano-scale energy harvesting device (100). Accordingly, introducing PbSeTe or PbTe, doped with the transition metal into the emitter electrode (102), the collector electrode (104), and the nano-particle clusters (304) and (306), increases conversion of thermal energy to electrical energy through increasing the rate of transfer of electrons through the nano-scale energy harvesting device (100).

A plurality of nano-scale energy harvesting devices (100) is distinguished by at least one embodiment having the thermoelectric energy conversion features described herein. The nano-fluid (302) is selected for operation of the nano-scale energy harvesting devices (100) within one or more temperature ranges. In one embodiment, the temperature range of the associated nano-scale energy harvesting device (100) is controlled to modulate a power output of the device (100). In general, as the temperature of the emitter electrode (102) increases, the rate of thermionic emission therefrom increases. The operational temperature ranges for the nano-fluid (302) are based on the desired output of the nano-scale energy harvesting device (100), the temperature ranges that optimize thermionic conversion, the temperature ranges that optimize thermoelectric conversion, and fluid characteristics. Therefore, different embodiments of the nano-fluid (302) are designed for different energy outputs of the device (100). For example, in one embodiment, the temperature of the nano-fluid (302) should be maintained at less than 250° C. to avoid deleterious changes in energy conversion due to the viscosity changes of the dielectric medium (308) above 250° C. In one embodiment, the temperature range of the nano-fluid (302) for substantially thermionic emission only is approximately room temperature (i.e., about 20° C. to about 25° C.) up to about 70-80° C., and the temperature range of the nano-fluid (302) for thermionic and thermo-electric conversion is above 70-80° C., with the principle limitations being the temperature limitations of the materials. The nano-fluid (302) for operation including thermoelectric conversion includes a temperature range that optimizes the thermoelectric conversion through optimizing the power density within the nano-scale energy harvesting device (100), thereby optimizing the power output of the device (100). In at least one embodiment, a mechanism for regulating the temperature of the first nano-fluid (302) includes diverting some of the energy output of the device (100) into the nano-fluid (302). Accordingly, the apertures (108) of specific embodiments of the nano-scale energy harvesting device (100) may be filled with the nano-fluid (302) to employ thermoelectric energy conversion with thermionic energy conversion above a particular temperature range, or thermionic energy conversion by itself below that temperature range.

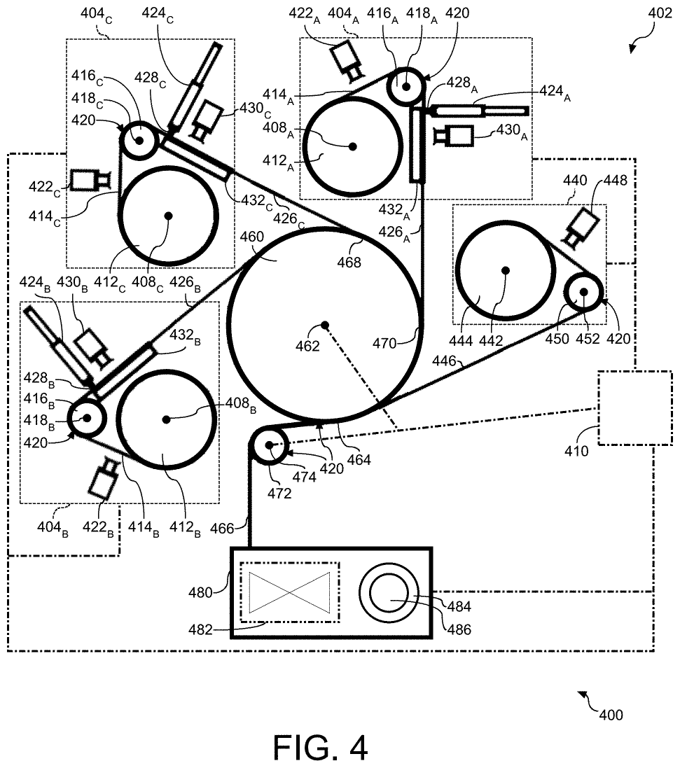

Referring to FIG. 4, a diagram (400) is provided to illustrate a schematic view of one embodiment of a manufacturing system (402) for the nano-scale energy harvesting devices (100). The manufacturing system (402) includes a plurality of dispensing stations. In one embodiment, the system (402) includes four dispensing stations including a first dispensing station (404_{A}), a second dispensing station (404_{B}), a third dispensing station (404_{C}), and a fourth dispensing station (406). In one embodiment, the system (402) includes less than four dispensing stations. In one embodiment, the system (402) includes more than four dispensing stations. Each of the four dispensing stations (404_{A})-(404_{C}) and (406) are discussed further herein.

The first dispensing station (404_{A}) includes a first dispenser (408_{A}). In one embodiment, the first dispenser (408_{A}) is an idle spindle that rotates about a predetermined axis. In one embodiment, the first dispenser (408_{A}) is a shaft that is driven by a drive device, e.g., such as but not limited to, an electric stepper motor, a pneumatic motor, a variable frequency drive, and an induction motor. In one embodiment, the first dispenser (408_{A}) is controlled through a control system (410) operatively coupled to the first dispensing station (404_{A}). In one embodiment, the control system (410) utilizes a processor to manage operation of the first dispensing station (404_{A}). In one embodiment, the control system (410) includes a distributed control scheme. In one embodiment, the control system (410) includes a programmable logic controller (PLC). In one embodiment, the control system (410) includes one of more field-programmable gate arrays (FPGAs). In one embodiment, the operable coupling of the control system (410) to the first dispenser station (404_{A}) is wireless, wired, or a combination thereof. In one embodiment, the first dispenser (408_{A}) is a spindle or guide that receives a first repository (412_{A}) or spool of a first material (414_{A}) that has a first work function value. In one embodiment, the first material (414_{A}) is an emitter electrode (102), including the polyester film backing (116) in contact with the aluminum (Al) layer (118), and a patterned coating of cesium oxide (Cs₂O) (134) on the Al layer (118). In one embodiment, the first material (414_{A}) is in the form of a nano-web, i.e. a material or materials where a least one of the dimensional measurements is within the nanometer range as described herein. In one embodiment, the first dispensing station (404_{A}) receives and dispenses any material that enables operation of the system (402) as described herein. Accordingly, a first dispensing station (404_{A}) includes a first dispenser (408_{A}) that dispenses an emitter electrode (102) in the form of a nano-web.

The first dispensing station (404_{A}) also includes a first guide (416_{A}) that includes a spindle (418_{A}) or shaft in operable communication with the first dispenser (408_{A}). In one embodiment, the spindle (418_{A}) is an idle shaft that rotates about a predetermined axis. In one embodiment, the spindle (418_{A}) is a shaft that is driven by a drive device, e.g., and without limitation, an electric stepper motor, a pneumatic motor, a variable frequency drive, and an induction motor. In one embodiment, the spindle (418_{A}) is controlled through the control system (410) that is operatively coupled to the first dispensing station (404). In one embodiment, the first guide (416_{A}) is a portion of a larger guide assembly (420) described further herein. The first guide (416_{A}) provides support to the first material (414_{A}) and leads or otherwise introduces the first material (414_{A}) as it exits, e.g. unspools, from the first repository (412_{A}). In one embodiment, and as discussed further below, the first guide (416_{A}) changes the direction of the first material (414_{A}). The first dispensing station (404_{A}) further includes a first sensing device (422_{A}). In one embodiment, the first sensing device (422_{A}) is a camera that provides visual feedback of the first material (414_{A}) as it unspools from the first repository (412_{A}). In one embodiment, the visual feedback is displayed on an operatively coupled control station (not shown), e.g. visual display. In one embodiment, the visual feedback is transmitted to the control system (410) for modulating the rotational rate and the alignment of the first dispenser (408_{A}) and the first guide (416_{A}) to maintain an alignment of the first material (414_{A}) within predetermined parameters. In one embodiment, a position sensing instrument such as, and without limitation, a displacement sensor, or a magneto-restrictive position sensor are employed in place of or in combination with the first sensing device (422_{A}). Accordingly, the first guide (416_{A}) is operably coupled to the first dispenser (408_{A}) to maintain alignment of the first material (414_{A}) during operation of the system (402).

The first dispensing station (404_{A}) includes a first plurality of electrospray devices (424_{A}). In one embodiment, the electrospray devices are positioned to deposit or apply nanostructures to the oppositely positioned surfaces of the dispensed material. For example, the dispensing station (404_{A}) may be inverted or rotated up to 180 degrees (not shown) to deposit or apply the nanostructures. In one embodiment, the coating of Cs₂O (134) is not positioned on the first material (414_{A}) prior to positioning the first repository (412_{A}) on the first dispenser (408_{A}), and the electrospray devices (424_{A}) deposit the coating of Cs₂O (134) on the first material (414_{A}) to fabricate an emitter electrode (426_{A}), e.g. nano-web. In one embodiment, the electrospray device(s) (424_{A}) deposit any material on the first material (414_{A}) that enables operation of the system (402) as described herein. In one embodiment, with the coating of Cs₂O (134) previously positioned on the first material (414_{A}), the electrospray devices (424_{A}) are idle. In one embodiment, each electrospray device (424_{A}) is a nano-scale electrospray deposition apparatus that produces an expelled stream of droplets (428_{A}) that is sufficiently focused to provide deposition control and accuracy on the nano-scale level. In one embodiment, the first dispensing station (404_{A}) includes three electrospray devices (424_{A}) arranged in an array. In one embodiment, the first dispensing station (404_{A}) includes more or less than three devices (424_{A}). In one embodiment, the first dispensing station (404_{A}) includes more than one array of electrospray devices (424_{A}). In one embodiment, the electrospray devices (424_{A}) are operably coupled to the control system (410) to modulate the rate and direction of deposition of Cs₂O (134) on the first material (414_{A}) to form the emitter electrode nano-web (426_{A}). In one embodiment, the stream of droplets (428_{A}) is one of intermittent and continuous, or a combination thereof, for each of the individual electrospray devices (424_{A}) as a function of the desired pattern on the AL layer (118). The deposition of the Cs₂O (134) on the Al layer (118) decreases the work function value. Accordingly, the first dispensing station (404_{A}) deposits a coating of Cs₂O (134) on those embodiments of the first material (414_{A}) that are positioned on the first dispenser (408_{A}) without a previously deposited coating of Cs₂O (134).

The first dispensing station (404_{A}) further includes a second sensing device (430_{A}) that is similar to the first sensing device (422_{A}). The second sensing device (430_{A}) is operably coupled to the control system (410) to provide real-time feedback of the deposited coating of Cs₂O (134) on the emitter electrode nano-web (426_{A}). In one embodiment, the first dispensing station (404_{A}) includes a high voltage (HV) electro-magnetic (EM) field generation device (432_{A}) that generates an HVEM field that facilitates precise deposition of the Cs₂O coating (134) on the Al layer (118). In one embodiment, the field generation device (432_{A}) is operably coupled to the control system (410). Accordingly, the first dispensing station (404_{A}) dispenses a first material (414_{A}) in the form of an emitter electrode nano-web (426_{A}) or fabricates the emitter electrode nano-web (426_{A}) through deposition of a coating of Cs₂O (134) on the Al layer (118).

The manufacturing system (402) also includes the second dispensing station (404_{B}) that is similar to the first dispensing station (404_{A}). In one embodiment, the second dispensing station (404_{B}) includes a second dispenser (408_{B}) that receives and dispenses a second repository (412_{B}) of a second material (414_{B}). The second dispensing station (404_{B}) also includes a second guide (416_{B}) that includes a spindle (418_{B}), where the second guide (416_{B}) is a portion of the guide assembly (420). The second dispensing station (404_{B}) further includes a third sensing device (422_{B}) that is similar to the first sensing device (422_{A}). The second dispensing station (404_{B}) further includes a second plurality of electrospray devices (424_{B}) that fabricate a collector electrode nano-web (426_{B}) through a second expelled stream of droplets (428_{B}) when in service. The second dispensing station (404_{B}) also includes a fourth sensing device (430_{B}) that is similar to the second sensing device (430_{A}) and a second HVEM field generation device (432_{B}) that is similar to the first HVEM field generation device (432_{A}). In one embodiment, with the coating of Cs₂O (164) previously positioned on the second material (414_{B}), the electrospray devices (424_{B}) are idle. In one embodiment, the second plurality of electrospray devices (424_{B}) deposit the coating of Cs₂O (164) on the second material (414B). The deposition of the Cs₂O (134) on the Pt layer (148) decreases the work function value, which in one embodiment is decreased from approximately 5.65 eV for Pt to a work function value of about 0.88 eV. Similarly, deposition, the layer (148) is comprised of Gold, Au, and deposition of the Cs₂O (134) on the Au layer (148) decreases the work function value, which in one embodiment is decreased from approximately 5.45 eV for Au to a work function value of about 0.66 eV. In a manner similar to that of the first dispensing station (404_{A}), the second dispenser (408_{B}), the spindle (418_{B}) of the second guide (416_{B}), the third sensing device (422_{B}), the second plurality of electrospray devices (424_{B}), the fourth sensing (430_{B}), and the second HVEM field generation device (432_{B}) are operably coupled to the control system (410). Accordingly, the second dispensing station (404_{B}) introduces the collector electrode (104) in the form of a nano-web (426_{B}) to the manufacturing process as described herein, where the work function value of the collector electrode nano-web (426_{B}) is different from, i.e. greater than the work function value of the emitter electrode nano-web (426_{A}).

The manufacturing system (402) further includes the third dispensing station (404_{C}) that is similar to the first and second dispensing stations (404_{A}) and (404_{B}), respectively. In one embodiment, the third dispensing station (404_{C}) includes a third dispenser (408_{C}) that receives and dispenses a third repository (412_{C}) of a third material (414_{C}). The third dispensing station (404_{C}) also includes a third guide (416_{C}) that includes a spindle (418_{C}), where the third guide (416_{C}) is a portion of the guide assembly (420). The third dispensing station (404_{C}) further includes a fifth sensing device (422_{C}) that is similar to the first and third sensing devices (422_{A}) and (422_{B}), respectively. A third plurality of electrospray devices (424_{C}) fabricates a spacer nano-web (426_{C}) through a third expelled stream of droplets (428_{C}) when in service. The third dispensing station (404_{C}) also includes a sixth sensing device (430_{C}) that monitors the deposition of the nano-fluid (302) in the apertures (206) of the spacer (200). The third dispensing station (404_{C}) also includes a third HVEM field generation device (432_{C}) to facilitate precise deposition of the nano-fluid (302) in the apertures (206). The third plurality of electrospray devices (424_{C}) deposits the nano-fluid (302) into the apertures (206). Therefore, in one embodiment, the third electrospray devices (424_{C}) have a different configuration that that of the first and second electrospray devices (424_{A}) and (424_{B}), respectively. The nano-fluid (302) does not require a drying time as does the Cs₂O (134) and (164) (see FIG. 5), because the nano-fluid (302) remains in a fluid form. In a manner similar to that of the first and second dispensing stations (404_{A}) and (404_{B}), respectively, the third dispenser (408_{C}), the spindle (418_{C}) of the third guide (416_{C}), the fifth sensor (422_{C}), the third plurality of electrospray devices (424_{C}), the sixth sensor (430_{C}), and the third HVEM field generation device (432_{C}) are operably coupled to the control system (410). In one embodiment, the emitter electrode nano-web (426_{A}) and the collector electrode nano-web (426_{B}) are offset from the separation material nano-web (426_{C}) during the manufacturing process performed by the manufacturing system (402) as shown and described in FIGS. 2A and 2B. Therefore, alignment of the three nano-webs (426_{A}), (426_{B}), and (426_{C}) as described herein includes the offsets. Accordingly, the third dispensing station (404_{C}) introduces the spacer (200) in the form of a nano-web (426_{C}) to the manufacturing process as described herein, where the spacer nano-web (426_{C}) is positioned between the emitter electrode (426_{A}) and the collector electrode (426_{B}).

Rather than a nano-web material-based third dispensing station (404_{C}), in one embodiment, the third dispensing station (404_{C}) may be spray based. In one embodiment, the spacer material is sprayed onto the emitter electrode nano-web (426_{A}) downstream from the electrospray devices (424_{A}) where the Cs₂O coating (134) is positioned on the first material (414_{A}) to at least partially cover or communicate with the coating (134). The spacer material is electrosprayed through one or more electrospray devices similar to device (424_{A}). One or more spacer material electrospray devices are positioned sufficiently downstream from the electrospray devices (424_{A}) to permit adequate drying of the coating (134) (see FIG. 5). The spacer material is patterned on the emitter electrode nano-web (426_{A}) to define apertures similar to apertures (206). Further downstream of the spacer material spray device(s), the third electrospray device(s) (424_{C}) is positioned to place the nano-fluid (302) into the apertures, where the device(s) (424_{C}) are positioned sufficiently downstream from the spacer material spray devices to allow the spacer material to sufficiently dry prior to receiving the nano-fluid (302) (see FIG. 5). In one embodiment, the spacer material is sprayed onto the collector electrode (426_{B}) downstream of where the Cs₂O coating (164) is positioned on the second material (414_{B}) through the electrospray device(s) (424_{B}) where the process is similar to that for the emitter nano-web (426_{A}). In one embodiment, to enable the offsets of the of the emitter electrode (426_{A}) and the collector electrode (426_{B}) with respect to the separation material, each of the electrodes (426_{A}) and (426_{B}) receive application of a portion of the separation material spray in a pattern that effectively represents the offsets produced with the separation material (426_{C}) (see FIGS. 2A and 2B). Accordingly, the spacer material may be in the form of a nano-web or a sprayed material.

The manufacturing system (402) further includes the fourth dispensing station (440) that, in one embodiment, is configured differently than the first, second, and third dispensing stations (404_{A}), (404_{B}), and (404_{C}), respectively. In one embodiment, the fourth dispensing station (440) is configured similarly to the first, second, and third dispensing stations (404_{A}), (404_{B}), and (404_{C}). The fourth dispensing station (440) includes a fourth dispenser (442) that receives a fourth repository of material (444), where the fourth material (446) is a casing, or sheathing material (446) that encases the combined electrodes (426_{A}) and (426_{B}) and separation material (426_{C}), as discussed further herein. The fourth dispensing station (440) includes a seventh sensing device (448) that is similar to the first through sixth sensors (422_{A}), (430_{A}), (422_{B}), (430_{B}), (422_{C}), and (430_{C}), respectively. The seventh sensing device (448) monitors the dispensing of the casing material (446) from the fourth repository (444) by the fourth dispenser (442). The fourth dispensing station (440) further includes a fourth guide (450) that includes a fourth spindle (452), where the fourth guide (450) is a portion of guide assembly (420). The fourth dispenser (442), the spindle (452), and the seventh sensing device (448) are operatively coupled to the control system (410). Accordingly, the manufacturing system (402) includes a fourth dispensing station (440) that dispenses a casing material (446) for manufacturing the electric power harvesting devices (100).

The manufacturing system (402) further includes a guide assembly (420), or a guide system that directs the flow of the four materials (426_{A}), (426_{B}), (426_{C}), and (446). In one embodiment, the guide assembly (420) includes a centrally positioned element (460), hereinafter referred to as a center wheel, that is in operable communication with the dispensing stations (404_{A}), (404_{B}), (404_{C}), and (440) such that the dispensing stations (404_{A}), (404_{B}), (404_{C}), and (440) are in operable communication with each other. In one embodiment, the center wheel (460) is an idler wheel that includes an idler spindle (462) that provides alignment and free rotation of the wheel (460). In this embodiment, a device external to wheel (460) provides a force to pull the four materials (426_{A}), (426_{B}), (426_{C}), and (446) as discussed further herein. In one embodiment, the spindle (462) is operably coupled to the control system (410) to modulate the position of the wheel (460) with respect to the dispensing stations (404_{A}), (404_{B}), (404_{C}), and (440). In one embodiment, the wheel (460) is a drive wheel that is driven through the spindle (462) that is rotatably coupled to a drive device (not shown), e.g. a motor as described herein for the spindle (408_{A}). In this embodiment, the spindle is operably coupled to the control system (410). The wheel (460) is operably coupled to the dispensing stations (404_{A}), (404_{B}), (404_{C}), and 440, respectively, through the respective guide rollers (416_{A}), (416_{B}), (416_{C}), and (452), that are portions of the guide assembly (420).

The guide assembly (420) positions the materials (426_{A}), (426_{B}), (426_{C}), and (446) at a joint proximal position (464) thereof to produce a fabricated electric power generation material (466) that is used to manufacture the electric power harvesting devices (100) as described further herein. As used herein, the term “joint proximal position” refers to portion of the manufacturing system (402) where two or more of the materials (426_{A}), (426_{B}), (426_{C}) and casing material (446) come into contact proximate to the wheel (460). The guide assembly (420) also positions the second material, e.g. the collector nano-web, (426_{B}) in a joint proximal position (468) with the third material, e.g. spacer nano-web, (426_{C}). The guide assembly (420) further positions the first and second materials (426_{B}) and (426_{C}), respectively, in a joint proximal position (470) with the first material, e.g. emitter electrode nano-web, (426_{A}). The guide assembly (420) further includes a fifth guide (472) that includes a spindle (474). The fifth guide (472) is similar to the guides (416_{A}), (416_{B}), (416_{C}), and (450). The spindle (474) is similar to spindles (418_{A}), (418_{B}), (418_{C}), and (452). The fifth guide (472) provides alignment to the fabricated electric power generation material (466) and directs the material to a receiving station (480), i.e. a receiver (480). In one embodiment, the fifth guide (472) is coupled to a drive device, e.g. a motor similar to that described for spindle (408_{A}). In this embodiment, the fifth guide (472) provides the motive force to pull the material (466) and drive rotation of the wheel (460), which in turn provides a pulling force on the nano-web materials (426_{A}), (426_{B}), (426_{C}), and casing material (446) to rotate the respective guides (416_{A}), (416_{B}), (416_{C}), and (450), and the respective repositories (412_{A}), (412_{B}), (412_{C}), and (444). The fifth guide (472) also provides the force necessary to push the material (466) into the receiver (480). Also, in this embodiment, the fifth guide (472) is operably coupled to the control system (410) to regulate one or more of the speed of the spindle (474) and the position of the fifth guide (472). Accordingly, the guide assembly (420) guides the materials (426_{A}), (426_{B}), (426_{C}), and (446) to be joined at proximal positions (468), (470), and (464) to fabricate the electric power generation material (466) that is used to manufacture the electric power harvesting devices (100).

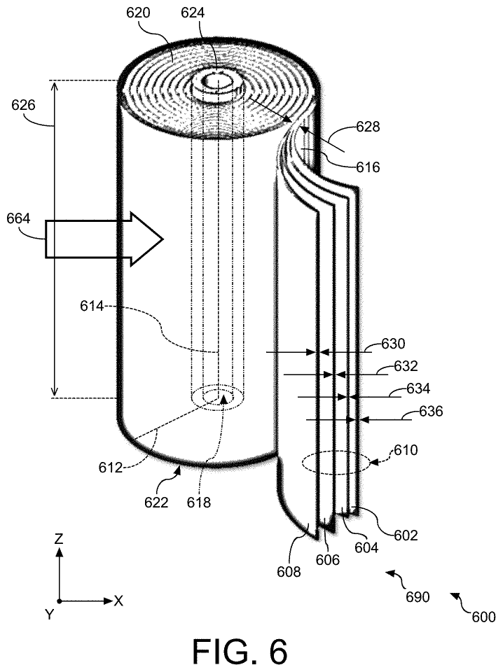

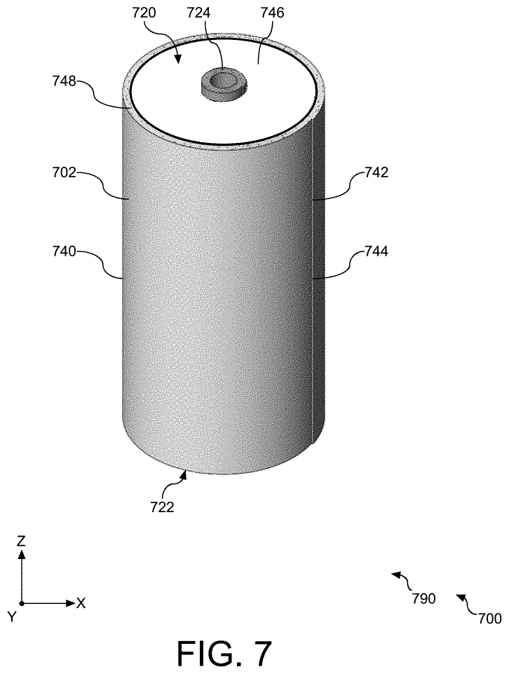

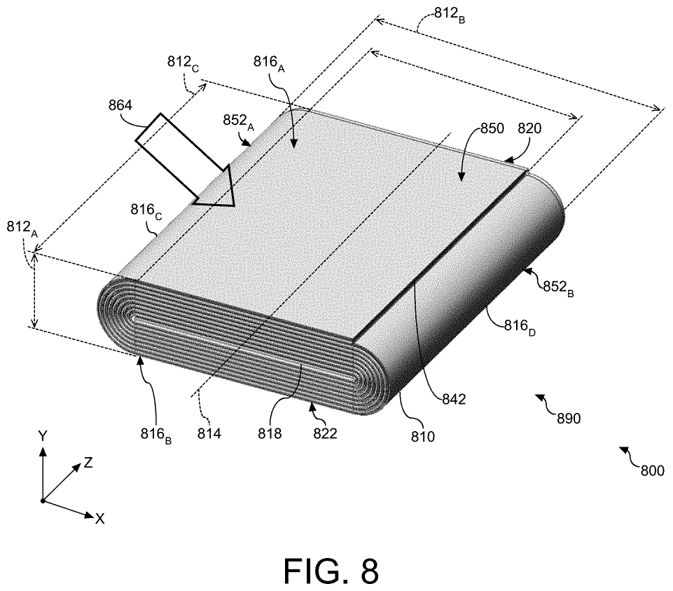

The receiver (480) is in operable communication, shown herein as in serial communication, with the fifth guide (472) and receives the electric power generation material (466) therefrom. In one embodiment, the receiver (480) includes a cutting device (482) that severs the incoming material (466) into planar severed portions, i.e. a sheet of material (466), with predetermined dimensions. In one embodiment, the sheet is approximately 36 in. (0.91 meters (m)) by approximately 4 inches (in.) (10.2 centimeters (cm) by approximately 0.079 in. (2 mm), although these dimensions should not be considered limiting. The receiver (480) also includes a winding device (484) operably coupled to the cutting device (482). The winding device (484) receives the severed sheets of material (466) and forms each severed sheet into an arcuate product (see FIGS. 6 and 7) through winding the material (466) on a winding shaft (486). In one embodiment, the winding shaft (486) is approximately ⅛^{th} of an inch in diameter and is at least partially threaded, although the size and threading should not be considered limiting. In one embodiment, a structural member (see FIGS. 6 and 7) acts as the shaft (484) and the shaft (484) remains coupled to the wound material (466). In one embodiment, the receiver does not include a cutting device and the material (466) is wound on the winder (484) for storage or further manufacturing. In one embodiment, the receiver (480) does not include the winder (484) and the severed sheets of material (466) that are generated by the cutting device (482) are collected for further manufacturing into a planar electric power harvesting device (see FIG. 8) or for transport to a remote winding device for further manufacturing into an arcuate device (see FIGS. 6 and 7). In one embodiment, the receiver (480) includes a drive device (not shown) similar to that described for the fifth guide (472) to pull the material (466) into the receiver (480). Accordingly, as shown and described, but not limited, the manufactured material (466) is formed into arcuate shapes or profiles.

Referring to FIG. 5, an enlarged schematic view (500) is provided to illustrate a portion of the manufacturing system (502), specifically, the second dispensing station (504_{B}). The collector electrode material (514_{B}) is dispensed from a collector electrode material repository (512_{B}) and is dispensed to a guide (516_{B}) with the third sensing device (522_{B}) providing alignment feedback to the control system (410). The guide (516_{B}) leads or otherwise introduces the material (514_{B}) to traverse the electrospray device (524_{B}) to receive the coating of Cs₂O (164), which in one embodiment is a patterned coating. The material (514_{B}) receives the coating (164) from the device (524_{B}) in the form of a second expelled fluid, e.g. stream, of droplets (528_{B}). A nozzle (590) is positioned a distance (592) from the material (514_{B}) to deposit the coating (164) at a first position (594). In one embodiment, the distance (592) is pre-determined or configurable. The distance (592), sometimes referred to as a “critical distance,” is based on factors that include, without limitation, a composition of the material being sprayed, a composition of the receiving substrate, a velocity of the coating droplets (528_{B}), a concentration of the droplets (528_{B}), and a dispersion of the droplets (528_{B}) such that a pattern or precise pattern of the coating (164) is positioned on the electrode material (514_{B}) to fabricate the collector electrode nano-web (526_{B}).

The fourth sensing device (530_{B}) monitors the coating (164) on the collector electrode (526_{B}), e.g. nano-web, and the distance (592). In one embodiment, the feedback from the sensing device (520_{B}) is transmitted to the control system (410) to regulate the position of the electrospray device (524_{B}) to modulate the distance (592). In one embodiment, the feedback from the sensing device (520_{B}) may be used to regulate one or more of, without limitation, the speed of material (514_{B}) dispensed from the repository (512_{B}), the position of the repository (512_{B}), the position of the guide (516_{B}), and the position of the center wheel (560). Accordingly, the distance (592) between the electrospray device (524_{B}) and the material (514_{B}) is subject to control and management.

A distance (596) between the first position (594) and the associated joint proximal position (568) where collector electrode (526_{B}) is contacted by spacer nano-web (526_{C}) is determined, or in one embodiment pre-determined, to allow sufficient drying time for the Cs₂O coating (164). The distance (596) is based on one or more of, without limitation, a composition of the material being sprayed, a composition of the receiving substrate, the amount of material sprayed, and the speed of the collector electrode (526_{B}). Similarly, a distance between the deposition of the Cs₂O coating (134) on the emitter electrode (426_{A}) and the joint proximal position (464) is determined. In one embodiment, the distance (596) may be regulated through modulation of the positions of the guide (516_{B}) and the center wheel (560). In one embodiment, meeting the requirement of the drying time is accomplished through modulation of the speed of the repository (512_{B}). Accordingly, the manufacturing system (502) provides for an adequate drying time for the Cs₂O coatings (164) and (134).

As described elsewhere herein, in one embodiment, rather than a nano-web material-based third dispensing station (404_{C}), the third dispensing station is used to spray the spacer material onto either the emitter or collector electrode nano-web (426_{A}) and (426_{B}), respectively. The spacer material is electrosprayed through one or more electrospray devices similar to devices (424_{A}). The spacer electrospray devices are positioned downstream from the electrospray devices (424_{A}) and (424_{B}), respectively, to permit adequate drying of the coating (134) or (164), respectively. The spacer spray material is positioned on the first material (414_{A}) or the second and the second material (414_{B}), respectively, to at least partially cover the coating (134) or (164), respectively. In a manner similar to that for the Cs₂O coatings (134) and (164), the spacer material electrospray devices are positioned sufficiently apart from the wheel (560) and the associated joint proximal position (468), which in one embodiment may be less than 1.0 cm, to permit adequate drying of the sprayed spacer material. Accordingly, a predetermined distance is positioned between the electrospray devices for spraying the spacer material and the joint proximal position to allow for adequate drying of the space material.

Referring to FIG. 6, a diagram (600) is provided illustrating a schematic perspective view of one embodiment of a nano-scale energy harvesting device (690) that may be manufactured as described herein, i.e., having an arcuate profile. The device (690) is not shown to scale. The device (690), also referred to herein as a port generation device, is manufactured by the manufacturing system (402) with a plurality of layers of materials, as described in detail herein. In one embodiment, the device (690) is manufactured with a plurality of separate layers, shown herein as four separate layers. A first layer (602) is referred to as a casing or sheathing that protects one or more of the inner layers and facilitates heat transfer in and out of the device (690). In one embodiment, the casing layer (602) is fabricated from the casing material (446). In one embodiment, the first layer (602) is manufactured from a thermally conductive and electrically insulating material. A second layer (604) includes the emitter electrode fabricated from the emitter electrode nano-web (426_{A}). A third layer (606) includes the separation material (also referred to herein as a standoff and spacer) fabricated from the spacer nano-web (426_{C}). In one embodiment, the third layer (606) is referred to herein as a spacer. A fourth layer (608) includes the collector electrode fabricated from the collector electrode nano-web (426_{B}). The emitter electrode (604), the spacer (606), and the collector electrode (608) are fabricated and configured as shown and described in FIGS. 1-5. The nano-fluid (112) and (302) is positioned in apertures (108) and (206) of the separation material (606), e.g. third layer. The outer casing (602), e.g. first layer, is in direct contact with the emitter electrode (604), e.g. second layer, and the emitter electrode (604), e.g. the second layer, and the collector electrode (608), e.g. fourth layer, are in direct contact with the spacer (606). Layers (602)-(608) are shown peeled away for clarity and illustrative purposes. In one embodiment, the layers (602)-(608) define a composite layer (610) of the electric power generation material (466) that is used to manufacture the electric power harvesting devices (690). Accordingly, the outer casing (602) is in contact with the emitter electrode (604) to provide heat transfer, protective, and sealing features to device (100).

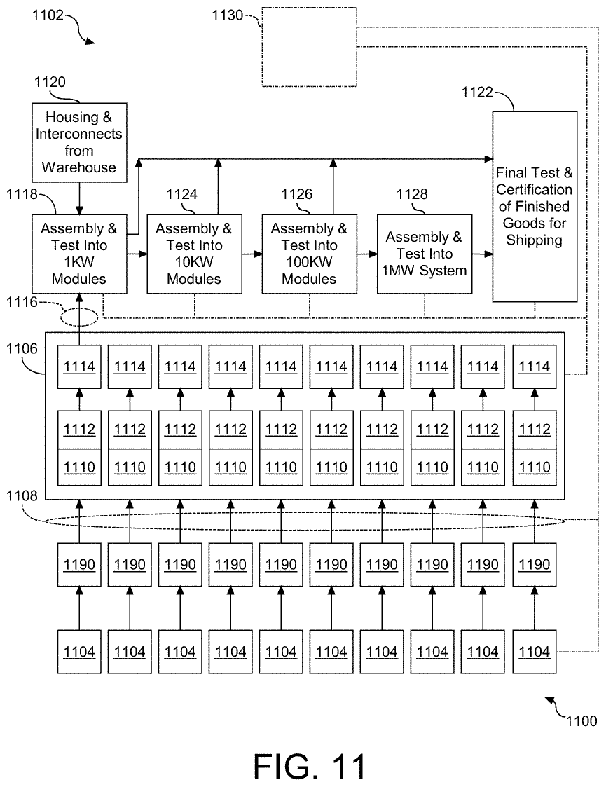

The device (690) is shown herein with an arcuate or cylindrical configuration with a defined radius (612) extending from an axial centerline (614) to an outermost surface (616) of the device (690). The axial centerline (614) extends parallel to the Z-axis and the radius (612) is defined in a plane defined by the X-axis and Y-axis such that the radius (612) and axial centerline (614) are orthogonal. The device (690) includes an axial aperture (618), shown in phantom, coincident with the axial centerline (614) extending from a first base area (620) to an opposing second base area (622). In one embodiment, a structural member (624) is inserted into and received by the axial aperture. The structural member (624) extends from the first base area (620) to the second base area (622), and in one embodiment, the structural member (624) protrudes from one or both of the base areas (620) and (622). In one embodiment, the structural member (624) is fabricated from one or more materials that are both thermally and electrically conductive, as well as chemically compatible with the materials of the layers (602)-(608). In other embodiments, the structural member (624) is fabricated from materials that are either thermally or electrically conductive. In one embodiment, layers (604) to (608) are wrapped around the structural member (624) during winding of the composite layer (610) about the member (624) in the receiver (480) with winding device (484). In one embodiment, the structural member (624) is inserted into the axial aperture (618) with an insertion device (see FIG. 11). Accordingly, the structural member (624) is configured to transfer heat energy and electrical energy generated within the device (690) away from the device (690).

The fourth layer (608), e.g. the collector electrode, is electrically coupled to the structural member (624) to provide at least a partial electrical flow path. The composite layer (610) extends from the structural member (624) in a spiral configuration, where the spiral configuration has a common center defined by the axial centerline (614) to further define a concentric configuration. The axial aperture (618) further defines a toroidal configuration with respect to the spiral wound configuration of the composite layer (610). Accordingly, the arcuate electric power harvesting device (690) has features that are spiral, concentric, cylindrical, and toroidal.

In one embodiment, the arcuate electric power harvesting device (690) has a length (626) measured along the Z-axis of approximately 10 mm to about 2.0 m. The radius (612) of device (690) is approximately 0.635 cm (e.g. 0.25 in.) to about 5.1 cm (e.g. 2.0 in.). A thickness (628) of the composite layer (610) is approximately 0.005 mm to about 2 mm. A thickness (630) of the collector electrode (608) is approximately 0.005 mm to about 2.0 mm. A thickness (632) of the spacer (606) is approximately 1.0 nm to about 10 microns. A thickness (634) of the emitter electrode (604) is approximately 0.005 mm to about 2.0 mm. A thickness (of the outer casing (602) is approximately 0.005 mm to about 2.0 mm. A length of the composite layer (610), if laid out flat from the spiral configuration, is approximately 5.1 cm (e.g. 2.0 in.) to approximately 122 cm (e.g. 48.0 in.). Other embodiments include any dimensional characteristics that enable manufacturer and operation of the arcuate shaped device (690) as described herein.

A single device (690) can generate a voltage within a range extending between about 0.5 volts and 1.0 volts, depending on the contact potential difference (discussed further herein) induced between the emitter electrode (604) and the collector electrode (608) as a function of the materials used for each. In one embodiment, the device (690) generates about 0.90 volts. The device (690) can generate an electrical current within a range of approximately 5 amperes (amps) to approximately 10 amps. In one embodiment, the device (690) generates about 7.35 amps. Further, in one embodiment, the device (690) generates approximately 2.5 watts to approximately 10 watts. In one embodiment, the device (690) generates about 6.6 watts. A plurality of the devices (690) may be electrically connected in series for a specific voltage or in parallel for a specific current, or in series and parallel to satisfy both the voltage and current requirements. Accordingly, as described further herein, the arrangements of the devices (690) are scalable to provide sufficient electrical power from the watt range to the megawatt range for a variety of applications.

The structural member (624) performs both heat transfer and electrical conduction actions when the arcuate electric power harvesting device (690) is in service generating electricity. In addition, the structural member (624) provides structural integrity, and an anchor for an end cap (not shown). Structural member (624) is electrically coupled to an external circuit (not shown) to transmit the electrical power generated within the device (690) to loads on the external circuit. The structural member (624) is also coupled to a either a heat exchanger or a heat sink through a heat transfer member (not shown). In one embodiment, the heat transfer member (not shown) is fabricated from an electrically non-conductive material that has sufficient heat transfer characteristics to maintain the device (690) within a predetermined temperature range. In one embodiment, heat transfer member (not shown) is fabricated from, but not limited to, graphene, carbon composites, and similar materials. Accordingly, structural member (624), which is shown and described herein as having dual purposes, is positioned within the axial aperture (618) during the manufacturing process as described further herein.

The electric power harvesting device (690) generates electric power through harvesting heat energy (664). The emitter electrode (604) receives heat energy (664) from sources that include, without limitation, heat generating sources and ambient environments, and generates an electric current that traverses the apertures (206) via the nano-particle clusters (304) and (306) in the form of the electrons (312). The electric current reaches the collector electrode (608) and the current is transmitted through the structural member (624) to the external circuit to power the loads thereon. In one embodiment, the device (690) generates electrical power through placement in ambient, room temperature environments. Accordingly, the device (690) harvests heat energy (664), including waste heat, to generate useful electrical power.

Referring to FIG. 7, a diagram (700) is provided illustrating a perspective view of an arcuate electric power harvesting device (790). In one embodiment, device (790) is similar to device (690). In one embodiment, an outer casing (702) includes multiple layers (602) of the outer casing material (446) to fabricate the outer casing (702) with an enhanced robustness. The outer casing (702) of device (790) includes an external surface (740) that includes a seam (742) defined by one or more layers (602) of outer casing (702). In one embodiment, the seam (742) is defined by the composite layer (610). The seam (742) receives a sealant (744) to prevent ingress of contaminants and egress of device materials through the seam (742). In one embodiment, the sealant (742) is non-conductive to prevent short circuiting of the electrodes (604) and (608). In one embodiment, the sealant (744) is antimony-based. In another other embodiment, the sealant (744) is manufactured from a material that enables operation of an arcuate electric power harvesting device (690) and (790) as described herein.

A first base area (720) receives a sealant (746) that extends between a rim (748) defined by the outer casing (702) and a structural member (724) that is similar to structural member (624). In one embodiment, the sealant (746) is substantially similar to the sealant (744). In one embodiment, the sealant (746) is different from the sealant (744). The sealant (746) is also applied to a second base area (722), where the second base area (722) has a similar configuration to the first base area (720). The sealant (746) functions to provide protection of the electrodes (604) and (608), spacer (606), and nano-fluid (302) from environmental factors, such as debris, that may induce a short circuit between the electrodes (604) and (608) or contaminate the nano-fluid (302). In one embodiment, the sealants (744) and (746) are applied to the device (790) after the structural member (724) is inserted into the axial aperture (618) during the manufacturing process as described further herein. In addition, as described herein with respect to FIGS. 2A and 2B, the electrodes (604) and (608) (equivalent to electrodes (262) and (264), respectively) are offset distances (236) and (248), respectively, from the spacer (606). Therefore, the non-conducting sealant (746) resides around the lateral side edges (230) of the electrode (102) and the lateral side edges (242) of the electrode (104) that extend distances (236) and (248) beyond the spacer (606), respectively. Accordingly, the electric power harvesting device (790) is shown herein with sealants (744) and (746) that provide environmental protections for the device (790) and electrical insulation for the electrodes (604) and (608).

Referring to FIG. 8, a diagram (800) is provided illustrating a schematic perspective view of a nano-scale electric power harvesting device (890), hereinafter referred to as device (890) that may be manufactured as described herein, i.e. having a planar profile. The device (890) is not shown to scale. The power generation device (890) is manufactured by the manufacturing system (400) with a plurality of layers of materials similar to that described for arcual device (690). The device (890) includes a composite layer (810) that is similar to the composite layer (610), where the layers (602)-(608) similarly define the composite layer (810) of the electric power generation material (466) that is used to manufacture the planar electric power harvesting devices (890). Accordingly, the planar device (890) includes the sequence of adjacently positioned layers (602)-(608) as described for the arcuate device (690).

The electric power harvesting device (890) is shown herein with a planar or rectangular configuration with a first dimensional value (812_{A}) extending through an axial centerline (814) from a first external surface (816_{A}) to a second external surface (816_{B}) of the device (890). The axial centerline (814) extends parallel to the Z-axis and the first dimensional value (812_{A}) extends parallel to the Y-axis. The device (890) includes a second dimensional value (812_{B}) that extends parallel to the X-axis and a third dimensional value (812_{C}) that extends parallel to the Z-axis. The device (890) includes an axial aperture (818) (shown in phantom) coincident with the axial centerline (814) extending from a first base area (820) to an opposing second base area (822). In one embodiment, a planar structural member (not shown) similar to the cylindrical structural member (624) with the exception of the shape is inserted into and received by the axial aperture (818) in a manner similar to the structural member (624) inserted into the axial aperture (618) for the device (690). The planar structural member extends from the first base area (820) to the second base area (822), and in one embodiment, the planar structural member protrudes from one or both of the base areas (820) and (862). In one embodiment, layers (604) to (608) are wrapped around the structural member during winding of the composite layer (610) about the planar structural member in the receiver (480) with a winding device similar to the winding device (484), but configured to wind the electric power generation material (466) into the configuration shown in FIG. 8. In one embodiment, the planar structural member is inserted into the axial aperture (818) with an insertion device (see FIG. 11). Accordingly, the planar structural member is configured to transfer heat energy and electrical energy generated within the device (890) away from the device (890).

The planar device (890) includes a planar section (850) defined by the axial aperture (818) and two semi-cylindrical sections (852_{A}) and (852_{B}). The semi-cylindrical sections (852_{A}) and (852_{B}) define third and fourth external surfaces (816_{C}) and (816_{D}), respectively. The planar device (890) is manufactured through a process where the electric power generation material (466) is successively wrapped about the axial aperture (818) such that the material (466) defines successive overlapping composite layers (810). The overlapping composite layers (810) have a planar configuration in the planar portion (850) and have a 180-degree turn on each semi-cylindrical section (852_{A}) and (852_{B}) such that the composite layer (810) is continuous from the axial aperture (818) to a seam (842) defined at the first external surface (816_{A}) by the planar section (850) and semi-cylindrical section (852_{B}). The two semi-cylindrical sections (852_{A}) and (854_{B}) and the planar section (850) define a quasi-rectangular spiral configuration (discussed further below). Accordingly, the planar device (890) is manufactured with a continuous extent of the electric power generation material (466) to define semi-cylindrical sections (852_{A}) and (854_{B}) and a planar section (850).

The fourth layer (608), e.g. the collector electrode, is electrically coupled to the planar structural member to provide at least a partial electrical flow path. The composite layer (810) extends from the planar structural member in a quasi-rectangular spiral configuration, where the quasi-rectangular spiral configuration has a common center defined by the axial centerline (814) to further define a quasi-rectangular concentric configuration. The axial aperture (818) further defines a toroidal configuration with respect to the quasi-rectangular spiral wound configuration of the composite layer (810). Accordingly, the planar electric power harvesting device (890) has features that are spiral, concentric, rectangular, and toroidal.

In one embodiment, the planar electric power harvesting device (890) has a first dimensional value (812_{A}) of approximately 0.5 mm to about 5.0 mm, a second dimensional value (812_{B}) of approximately 30.0 mm to about 150 mm, and a third dimensional value (812_{C}) of approximately 20.0 mm to about 300 mm. A length of the composite layer (810), if laid out flat from the quasi-rectangular spiral wound configuration, is approximately 10 mm to about 2.0 m. Other embodiments include any dimensional characteristics that enable manufacturer and operation of the planar electric power harvesting device (890) as described herein.

A single device (890) can generate a voltage within a range extending between about 0.5 volts and 1.0 volts, depending on the contact potential difference (discussed further herein) induced between the emitter electrode (604) and the collector electrode (608) as a function of the materials used for each. In one embodiment, the device (890) generates about 0.90 volts. The device (890) can generate an electrical current within a range of approximately 5 amperes (amps) to approximately 10 amps. In one embodiment, the device (890) generates about 7.35 amps. Further, in one embodiment, the device (890) generates approximately 2.5 watts to approximately 10 watts. In one embodiment, the device (890) generates power equivalent or about the same as the device (690) shown in FIG. 6. A plurality of the devices (890) may be electrically connected in series for a specific voltage or in parallel for a specific current, or in series and parallel to satisfy both the voltage and current requirements. Accordingly, as described further herein, the arrangements of the devices (890) are scalable to provide sufficient electrical power from the watt range to the megawatt range for a variety of applications.

The electric power harvesting device (890) generates electric power through harvesting heat energy (864). The emitter electrode (404) receives heat energy (864) from sources that include, without limitation, heat generating sources and ambient environments, and generates an electric current that traverses the apertures (206) via the nano-particle clusters (304) and (306) in the form of the electrons (312). The electric current reaches the collector electrode (408) and the current is transmitted through the planar structural member to an external circuit to power the loads thereon. In one embodiment, the device (890) generates electrical power through placement in ambient, room temperature environments. Accordingly, the device (890) harvests heat energy (864), including waste heat, e.g. heats the ambient environment, to generate useful electrical power.

The outer casing layer (602) of the planar device (890) defines the first external surface (816_{A}), the second external surface (816_{B}), the third external surface (816_{C}), and the fourth external surface (816_{D}). In one embodiment, an overlap of the first and fourth external surfaces (816_{A}) and (816_{D}), respectively, define the seam (842). The seam (842) is similar to the seam (742) for the cylindrical device (790) and the seam (842) also receives a sealant (not shown in FIG. 8) similar to the sealant (744) to prevent ingress of contaminants and egress of device materials through the seam (842). In one embodiment, the outer casing (602) of the device (890) includes multiple layers of outer casing material (446) to fabricate the outer casing (602) with an enhanced robustness.

In addition, the first base area (820) receives a sealant (not shown n FIG. 8) that is similar to the sealant (746). The sealant is also applied to the second base area (822), where the second base area (822) has a similar configuration to the first base area (820). The sealant functions to provide protection of the electrodes (604) and (608), spacer (606), and nano-fluid (302) from environmental factors, such as debris, that may induce a short circuit between the electrodes (604) and (608) or contaminate the nano-fluid (302). In one embodiment, the sealants are applied to the device (890) after the planar structural member is inserted into the aperture (818) during the manufacturing process as described further herein. In addition, as described herein with respect to FIGS. 2A and 2B, the electrodes (604) and (608) (equivalent to electrodes (262) and (264), respectively) are offset distances (236) and (248), respectively, from the spacer (606). Therefore, the non-conducting sealant resides around the lateral side edges (230) of the electrode (102) and the lateral side edges (242) of the electrode (104) that extend distances (236) and (248) beyond the spacer (606), respectively. Accordingly, the electric power harvesting device (890) receives sealants that provide environmental protections for the device (890) and electrical insulation for the electrodes (604) and (608).

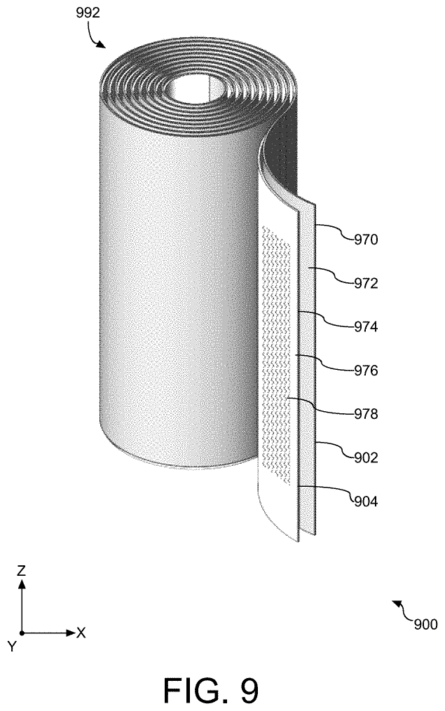

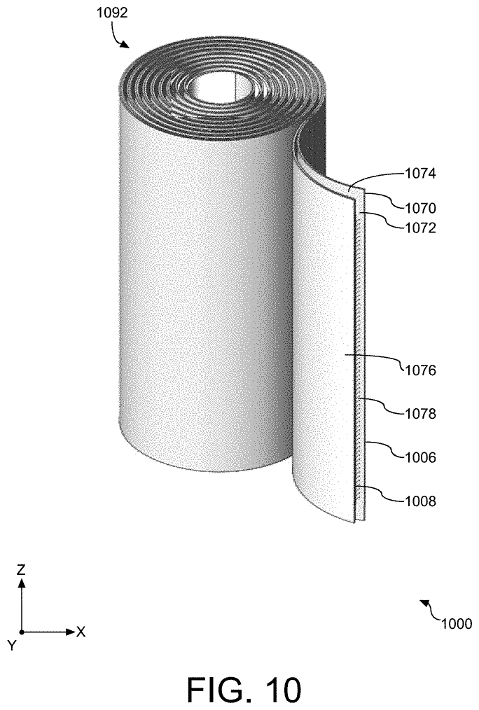

In one embodiment, the arcuate electric power harvesting devices (690) and (790) and the planar device (890) are manufactured from four separate repositories of materials as shown and described in FIG. 4. Referring to FIG. 9, a diagram (900) is provided illustrating a perspective view of a first repository (992) of layered materials (902) and (904), e.g. the first and second layers, that may be used to manufacture the electric power harvesting devices (690), (790), and (890) as described herein. Referring to FIG. 10, a diagram (1000) is provided illustrating a perspective view of a second repository (1092) of layered materials (1006) and (1008), e.g. the third and fourth layers, that may be used to manufacture the electric power harvesting devices (690), (790), and (890) as described herein.

Referring to FIG. 9, the first layer (902) is equivalent to the outer casing (602) and is hereon referred to as the outer casing (902). Similarly, the second layer (904) is equivalent to the emitter electrode (604) and is hereon referred to as the emitter electrode (904). The outer casing (902) includes a first surface (970) that defines the external surface (740) of the arcuate electric power harvesting devices (690) and (790) and external surfaces (816_{A}) through (816_{D}) of the planar device (890). The outer casing (902) also includes a second surface (972) that contacts the emitter electrode (904). The emitter electrode (904) includes a first surface (974) contacting the second surface (972) of the outer casing (902). The emitter electrode (904) also includes a second surface (976). In one embodiment, the second surface (976) is at least partially coated with Cs₂O (978), which in one embodiment is pre-applied to the second surface (976). In one embodiment, the Cs₂O (978) is applied to the second surface (976) during manufacturing of the electric power harvesting devices (690), (790), and (890).

Referring to FIG. 10, the third layer (1006) is equivalent to the separation material (606), and is hereon referred to as separation material (1006). Similarly, the fourth layer (1008) is equivalent to the collector electrode (608) and is hereon referred to as collector electrode (1008). The separation material (1006) includes a first surface (1070) that contacts the second surface (976) of the emitter electrode (904). The separation material (1006) also includes a second surface (1072). The collector electrode (1008) includes a first surface (1074) contacting the second surface (1072) of the separation material (1006). The collector electrode (1008) also includes a second surface (1076). In one embodiment, the first surface (1074) is at least partially coated with Cs₂O (1078), which in one embodiment is pre-applied to the first surface (1074). In one embodiment, the Cs₂O (1078) is applied to the first surface (1076) during manufacturing of the electric power harvesting devices (690), (790), and (890).

Referring to FIGS. 4, 9, and 10, the manufacturing system (402) may be adapted to use the first repository (992) and the second repository (1092) to fabricate the electric power generation material (466). In one embodiment, the first repository (992), including the casing layer (902) and the emitter electrode layer (904), is positioned on the first, third, or fourth dispensing stations (404_{A}), (404_{C}), and (444), respectively. The second repository (1092) including the spacer layer (1006) and the collector electrode layer (1008) is positioned on the second, third, or first dispensing stations (404_{B}), (404_{C}), and (404_{A}), respectively. The second repository (1092) is dispensed to the wheel (460) prior to the dispensing of the first repository (992) to fabricate the material (466) with the material dispensed from the first repository (992) being positioned over the material dispensed from the second repository (1092). The nano-fluid (302) is sprayed onto the spacer layer (1006) using the respective electrospray devices (424_{B}), (424_{C}), and (424_{A}). In one embodiment, any combination of repositories (412_{A}), (412_{B}), (412_{C}), (444). (992), and (1092) is used to fabricate the material (466). Accordingly, the manufacturing system (402) includes the flexibility to fabricate the electric power generation material (466) using two, three, or four repositories of materials.

Referring to FIG. 11, a flow diagram (1100) is provided illustrating one embodiment of a system (1102) to manufacture electric power generation modules and systems of modules with the nano-scale energy harvesting devices (1190) described herein. The devices (1190) are similar to the arcuate device (690) and the planar device (890). In one embodiment, all of the devices (1190) are arcuate. In one embodiment, all of the devices (1190) are planar. In one embodiment, the devices (1190) are a combination of arcuate and planar. The system (1102) includes a plurality of cell fabrication machines (1104) for the nano-scale energy harvesting devices (1190), where the cell fabrication machines (1104) are similar to the manufacturing systems (402) shown and described in FIG. 4. Ten machines (1104) are shown, however, this number is not limiting. The system (1102) is scalable to accommodate from a minimum of one machine (1104) up to multiple thousands of machines (1104). In one embodiment, each machine (1104) has an area footprint of approximately 0.5 m by 1.5 m to about 1.0 m by 2.5 m. The devices (1190) are transported from the machines (1104) to a cell manufacturing station (1106) by a first transport system (1108). In one embodiment, a single transport device (1108) transports the devices (1106) individually to the cell manufacturing station (1106) as they are manufactured by the machines (1104). In one embodiment, the first transport system (1108) is synchronized with the machines (1104) to transport a plurality of devices (1190) simultaneously or near-simultaneously, with the quantity of devices subject to transport being configurable. In one embodiment, the first transport system (1108) transfers the devices (1104) from a storage station (not shown) to the cell manufacturing station (1106). Accordingly, the first transport system (1108) transports the devices (1190) to a station (1106) for final manufacturing of a cell (described further herein).

The cell manufacturing station (1106) includes a plurality of devices to complete the manufacturing of a cell from the devices (1190). In one embodiment, the station (1106) includes a plurality of insertion devices (1110). The insertion devices (1110) insert the structural members, e.g. for the arcual devices (690), structural member (624) is inserted into the axial aperture (618). A planar structural member is inserted into the axial aperture (818) for the planar devices (890). In one embodiment, the station (1106) includes a plurality of sealing devices (1112). The sealing devices apply the sealant (744) to the seam (742) and the sealant (746) to the base areas (720) and (722) for the cylindrical device (790). Similarly, a sealant is applied to the seam (842) and base areas (820) and (822) of the planar device (890). The sealants are applied to the devices (1190) after insertion of the associated structural members to provide for effective isolation of the internals of the devices (1190) from external environmental hazards. In one embodiment, each insertion device (1110) and each sealing device (1112) operate individually as the transport system (1108) delivers a device (1190). In one embodiment, the cell manufacturing station (1106) is synchronized with the transport system (1106) to transport a plurality of devices (1190) simultaneously or near-simultaneously, with the quantity of devices subject to transport being configurable. In one embodiment, the insertion devices (1110) and the sealing devices (1112) are integrated into the cell fabrication machines (1104). Once the structural member is inserted in the device (1190), and the device (1190) is sealed, the device (1190) has been fully manufactured into a power generation nano-cell (1114) (e.g. see (790) in FIG. 7), where each cell (1114) is a self-contained electric power generation device. In one embodiment, the devices (1104) are referred to as a partially formed cell. In one embodiment, the severed portions of the fabricated electric power generation material (466) that are used to manufacture the electric power harvesting devices (1104) are referred to as partially formed cells. Accordingly, each device (1190) manufactured by the machines (1104) is fully manufactured into a cell (1114) by the cell manufacturing station (1106).

The system (1102) includes a second transport system (1116) that transports the cells (1114) to a first assembly and test station (1118). The second transport system (1116) is similar to the first transport system (1108). The first assembly and test station (1118) receives module housings and cell electrical interconnects (1120) from a warehouse to prepare a nano-scale electric power generation module (not shown) for receipt of the cells (1114). In one embodiment, a one kilowatt (kw) module, where 1 kw is non-limiting, receives approximately a plurality of cells (1114), where each cell (1114) is capable of generating approximately 6.6 watts. The station (1118) also includes a test device (not shown) that tests the cells (1114) in the module either together or individually. In one embodiment, once the 1 kw modules are assembled and tested, the 1 kw modules are subjected to a final station (1122) for final testing, certification, labeling as a finished good, and shipping. In one embodiment, the 1 kw modules are transported to a second assembly and test station (1124) that is similar to the first station (1118). For example, ten 1 kw modules are received by a 10 kw module (not shown), where ten modules and 10 kw are non-limiting values. In one embodiment, once the 10 kw modules are assembled and tested, the 10 kw modules are transported to the final station (1122). In one embodiment, the 10 kw modules are transported to a third assembly and test station (1126) that is similar to the first and second stations (1118) and (1124), respectively. In one embodiment, ten 10 kw modules are received by a 100 kw module (not shown), where 10 modules and 100 kw are non-limiting values. In one embodiment, once the 100 kw modules are assembled and tested, the 100 kw modules are transported to the final station (1122). In one embodiment, the 100 kw modules are transported to a fourth assembly and test station (1128) that is similar to the first, second, and third stations (1118), (1124), and (1126), respectively. In one embodiment, ten 100 kw modules are received by a 1 megawatt (MW) system (not shown), where 10 modules and 1 MW are non-limiting values. In one embodiment, once the 1 MW systems are assembled and tested, the 1 MW systems are transported to the final station (1122). The assignment of the term “modules” to the devices in the kw range and “system” to devices in the MW range should not be considered limiting. In one embodiment, systems in the kw range and modules in the MW range are envisioned. The process of assembling power systems with the assembled modules is scalable up to the gigawatt range. Accordingly, the system (1102) is scalable to manufacture electric power generation systems of any size and capacity from the cells (1114) manufactured as described herein.

A control system (1130) is operably coupled to the cell fabrication machines (1104), the first transport system (1108), the insertion devices (1110), the sealing devices (1112), the second transport system (1116), the assembly and testing stations (1118), (1124), (1126), and (1128), and the final station (1122). In one embodiment, the control system (1130) is similar to the control system (410). In one embodiment, the control system (410) is embedded within the control system (1130). In one embodiment, the control system (1130) is embedded within the control system (410). In one embodiment, the control system (410) and (1130) are separate systems that communicate with each other. The control system (1130) coordinates the transport of the devices (1190) through the process of being manufactured into cells (1114) and the subsequent assembly of the cells (1114) into power modules in the kilowatt range and the power modules into power systems in the megawatt through gigawatt ranges. Accordingly, the system (1102) includes the control system (1130) to regulate the processes described herein for FIG. 11 from the cell fabrication machines (1104) to the final station (1122).

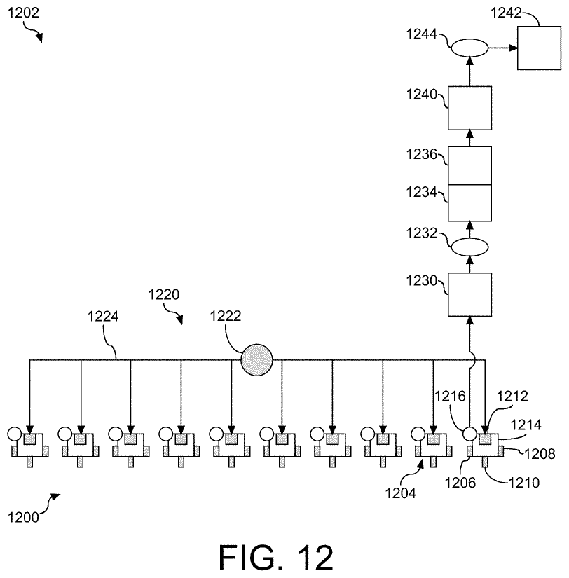

Referring to FIG. 12, a schematic view (1200) is provided to illustrate a one embodiment of a manufacturing system (1202) for the nano-scale energy harvesting devices (100), (690), (790), and (890). The system (1202) includes a plurality of cell fabrication machines (1204). Ten machines (1204) are shown, however, this number is not limiting. The system (1202) is scalable to accommodate one machine (1204) up to a multiple of thousands of machines (1204). Each machine (1204) includes a collector electrode dispenser (1206), an emitter electrode dispenser (1208), and a spacer dispenser (1210), where dispensers (1206), (1208), and (1210) are similar to dispensers (404_{A}), (404_{B}), and (404_{C}). Each machine (1204) also includes a plurality of electrospray devices (not shown FIG. 12) similar to the electrospray devices (424_{A}) and (424_{B}) to deposit a patterned coating of Cs₂O (134) and (164) on each of the emitter and collector electrodes (102) and (104), respectively prior to the spacer material (106) contacting the electrodes (102) and (104). An electrospray apparatus (1212) is positioned to spray the nano-fluid (302) onto one or more of the electrodes (102) and (104) and the spacer (106) prior to winding the assembled materials into a partially formed product. A transport device (1212) transports the wound, partially formed object to a vacuum chamber (1216) where infusion of the nano-fluid (302) into the apertures (206) of the spacer (106) is achieved. In one embodiment, the system (1202) includes a nano-fluid delivery system (1220) that includes a nano-fluid reservoir (1222) coupled in fluid communication with the nano-fluid electrospray apparatus (1212) through a plurality of fluid conduits (1224). Upon completion of the nano-fluid infusion, a partial cell (1230), similar to the partial cell (1190), is transported through a first transport system (1232) that is similar to the first transport system (1108), to an insertion device (1234) and a sealing device (1236), that are similar to insertion devices (1110) and sealing devices (1112), respectively. The finished cell (1240) is transported to the suite of assembly and testing stations (1242) by a second transport system (1244) that is similar to the second transport system (1116). The assembly and testing stations (1242) are similar to the assembly and testing stations (1118), (1124), (1126), and (1128), and the final station (1122). Accordingly, nano-fluid (302) is infused to manufacture the cells (1230).

As described herein, the present disclosure is directed generally to manufacturing an energy source, and more particularly, is directed to manufacturing nano-scale energy harvesting devices. Specific materials are either provided or fabricated and are joined to manufacture the nano-scale energy harvesting devices. The materials include electrodes fabricated from two different materials that are at least partially coated with a material such as Cs₂O to provide the two electrodes with different work function values. An emitter electrode and a collector electrode are fabricated, where the collector electrode had a larger work function value than the emitter electrode. A separation material is positioned between the two electrodes. Apertures within the separation material are filled with a nano-fluid that includes nano-particle clusters with greater work function values than either of the two electrodes. This arrangement of materials induces electron current flow from the emitter electrode, through the nano-fluid, to the collector electrode. The mechanisms for the electron transfer through the nano-fluid include Brownian motion of the nano-particle clusters and electron tunneling across distances. In one embodiment, the electron tunneling distances are less than 20 nm. The design of these devices enables ambient energy extraction at low temperatures (including room temperature). The devices described herein initiate electron flow due to differences in Fermi levels of the electrodes without the need for an initial temperature differential or thermal gradient. The electron current can be increased through the addition of heat energy to the emitter electrode and electrically connecting the device to an external circuit with loads thereon.

The systems to manufacture the nano-scale energy harvesting devices include a plurality of dispensers that receive repositories of the materials used to manufacture the devices. The materials on the repositories are dispensed toward a center wheel, where the materials are positioned to contact each other. For those electrode materials that do not arrive from the associated vendors with the Cs₂O coatings thereon, each associated dispenser for the electrodes includes electrospray devices to spray the Cs₂O coatings onto the electrodes. For those electrode materials that are provided with the Cs₂O coatings thereon, the electrospray devices are idled or set to an idle position or setting. The separation materials receive a nano-fluid from a plurality of electrospray devices positioned proximate to the associated dispenser. The distances between the materials dispensed from the repositories and the electrospray devices are determined for each material to optimize precise positioning of the sprayed materials on the unrolled materials. Also, the drying distances for the electrode sprays are determined to optimize drying on the unrolled electrode materials.

The manufacturing systems described herein are flexible with respect to accepting varying repositories of materials. In general, the devices include a plurality of layers of different materials that are taken from a respective material repository. In one embodiment, each of the materials for the layers may be assigned a particular dispenser. Also, the repositories may include more than one layer of material such that as few as two repositories may be used to manufacture the devices. In addition, the separation may be sprayed onto the electrodes rather than inserted between the electrodes.

The manufacturing systems described herein are also flexible with respect to the devices manufactured therefrom. The product resulting from the dispensers and the center wheel is the material to manufacture the devices is in the form of a web, e.g. nano-web, with four layers. The nano-web may be severed into planar pieces that are immediately transported to a winding device to produce an arcual-shaped product with the layers defining concentric, cylindrical spirals. The severed portions may be transported to a manufacturing device that will produce a planer product with concentric, quasi-rectangular spirals. The severed sections of the nano-web may be transported to a storage area for future device manufacturing. Regardless of whether the products are arcual or planar, the products receive final manufacturing including insertion of heat removal and electrically conductive materials in central apertures formed by the manufacturing process. The products are sealed to protect the internal aspects of the products which are now cells. The cells can be grouped in power generation assemblies that are modular in nature or are larger generation systems.

The nano-scale energy harvesting devices described herein are scalable across a large number of power generation requirements. The devices may be designed for applications requiring electric power in the milliwatts (mW), watts (W), kilowatts (kW), and megawatts (MW) ranges. Examples of devices for the mW range include, but are not limited to, those devices associated with the Internet of Things (IoT) (home appliances, vehicles (communication only)), handheld portable electronic devices (mobile phones, medical devices, tablets), and embedded systems (RFIDs and wearables). Examples of devices for the watts range include, but are not limited to, handheld sensors, networks, robotic devices, cordless tools, drones, appliances, toys, vehicles, utility lighting, and edge computing. Examples of devices in the kW range include, but are not limited to, residential off-grid devices (rather than backup fossil fuel generators), resilient/sustainable homes, portable generators, electric and silent transportation (including water-faring), and spacecraft. Examples of devices in the MW range include, but are not limited to, industrial/data center/institutional off-grid devices (e.g., uninterruptible power supplies), resilient complexes, urban centers, commercial and military aircraft, flying cars, and railway/locomotive/trucking/shipboard transportation. Accordingly, substantially any power demand in any situation can be met with the devices disclosed herein.

Aspects of the present embodiments are described herein with reference to one or more of flowchart illustrations and/or block diagrams of methods and apparatus (systems) according to the embodiments.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments. The embodiments were chosen and described in order to best explain the principles of the embodiments and the practical application, and to enable others of ordinary skill in the art to understand the embodiments for various embodiments with various modifications as are suited to the particular use contemplated. The implementation of the manufacturing systems of the nano-scale energy harvesting devices facilitates manufacturing these devices on a scale from individual devices to a factory-level scale to produce thousands of devices. Accordingly, the manufacturing systems for the nano-scale energy harvesting devices and the associated embodiments as shown and described in FIGS. 1-12, provide for producing electric power harvesting devices across a wide range of energy consumption requirements.

It will be appreciated that, although specific embodiments have been described herein for purposes of illustration, various modifications may be made without departing from the spirit and scope of the embodiments. In particular, the manufacturing systems for the nano-scale energy harvesting devices are shown as configured to manufacture these devices with a predetermined set of conditions with respect to the materials used. Alternatively, the manufacturing systems may be configured to manufacture these devices under a variety of conditions with respect to the materials used. Accordingly, the scope of protection of the embodiment(s) is limited only by the following claims and their equivalents.

1. A system comprising:
a first dispenser configured to dispense a first material, the first material having a first work function value;
a second dispenser configured to dispense a second material, the second material having a second work function value, the second work function value being different from the first work function value;
a third dispenser configured to deposit a separation material between the first material and the second material;
at least one first device positioned proximal to the third dispenser, the first device configured to deposit a fluid within at least a portion of the separation material dispensed from the third dispenser, the fluid having a third work function value, the third work function value different from the first and second work function values; and
a guide assembly operably coupled to the first, second, and third dispensers, the guide assembly configured to transport the first and second electrodes, the positioned separation material, and the fluid to a joint proximal position and form a fabricated product.

2. The system of claim 1, further comprising a fourth dispenser configured to deposit a casing material over a least a portion of the first material or the second material.

3. The system of claim 1, further comprising a receiver configured to receive the fabricated product.

4. The system of claim 1, wherein the guide assembly comprises:
at least one first guide in operable communication with the first dispenser;
at least one second guide in operable communication with the second dispenser; and
a wheel operatively coupled to the first and second guides.

5. The system of claim 4, wherein the guide assembly further comprises:
at least one third guide in operable communication with the third dispenser and the wheel; and
at least one fourth guide in operable communication with the wheel and a receiver to receive the fabricated product.

6. The system of claim 3, wherein the guide assembly and the receiver are in a serial relationship, the receiver comprising a cutting device positioned to sever the fabricated product into one or more severed portions having one or more predetermined characteristics.

7. The system of claim 6, wherein the receiver further comprises a winding device operably coupled to the cutting device, the winding device configured to wind one or more of the severed portions into an arcuate object.

8. The system of claim 6, wherein the receiver further comprises a winding device operably coupled to the cutting device, the winding device configured to wind one or more of the severed portions into an arcuate object having a cylindrical structure with a radius and an axial centerline orthogonal to the radius.

9. The system of claim 8, wherein the winding device is configured to form the arcuate object with a conduit coincident with the axial centerline.

10. The system of claim 9, further comprising a first insertion device configured to insert a heat transfer member at least partially into the conduit.

11. The system of claim 9, further comprising a second insertion device configured to insert an electrical conductor at least partially into the conduit.

12. The system of claim 6, further comprising a sealing device configured to deposit a sealing material on one or more surfaces of the severed portions.

13. The system of claim 6, further comprising the cutting device configured to sever the fabricated product into a plurality of planar portions.

14. The system of claim 1, wherein the first material is dispensed from further comprising:
a first repository configured to dispense the first material;
a second repository configured to dispense the second material; and
a third repository configured to dispense the separation material, the first, second, and third repositories being separately controlled repositories.

15. The system of claim 1, wherein the third dispenser is at least one second electrospray device configured to spray the separation material onto the first electrode and/or the second electrode.

16. The system of claim 15, wherein:
the third dispenser and the guide assembly are arranged relative to one another to provide a first distance extending between the dispensed separation material and the joint proximal position.

17. The system of claim 1, further comprising:
a fifth material extending over at least a portion of the first material, wherein the first material and the fifth material define a first electrode; and
a sixth material extending over at least a portion of the second material, wherein the second material and the sixth material define a second electrode.

18. The system of claim 1, further comprising:
at least one first electrospray device positioned proximal to the first dispenser, the first electrospray device configured to deposit at least one first electrospray material over at least a portion of the first material dispensed from the first dispenser to fabricate a first electrode comprising the first material and the first electrospray material, the fabricated first electrode having a fourth work function value, the fourth work function value being different from the first, second, and third work function values; and
at least one second electrospray device positioned proximal to the second dispenser, the second electrospray device configured to deposit at least one second electrospray material over at least a portion of the second material dispensed from the second dispenser to fabricate a second electrode comprising the second material and the second electrospray material, the fabricated second electrode having a fifth work function value, the fifth work function value being different from the first, second, third, and fourth work function values.

19. The system of claim 18, further comprising:
a first distance extending between the dispensed first material and the first electrospray device; and
a second distance extending between the dispensed second material and the second electrospray device.

20. The system of claim 19, further comprising:
a third distance extending between the first electrospray device and a position proximate to the forming of the joint proximal position, wherein the third distance is a first drying region of the sprayed first material; and
a fourth distance positioned between the second electrospray device and the position proximate to the forming of the joint proximal position, wherein the fourth distance is a second drying region of the sprayed second material.

21. The system of claim 19, further comprising:
a first sensor proximate the first electrospray device and configured to monitor the deposition of the fluid;
a second sensor proximate the second electrospray device and configured to monitor the deposition of the first electrospray material; and
a third sensor proximate the third electrospray device and configured to monitor the deposition of the second electrospray material.

22. The system of claim 21, wherein the first, second, and third sensors are cameras.

23. The system of claim 6, wherein the cutting device is configured to sever the fabricated product into a severed portion at least partially forms a cell.

24. The system of claim 23, wherein the partially formed cell is arcuate or planar.

25. The system of claim 24, wherein the first, second, and third dispensers, the guide assembly, and the cutting device define a first cell fabrication machine.

26. The system of claim 25, further comprising a plurality of cell fabrication machines.

27. The system of claim 26, further comprising a cell transport device to selectively transport a cell from the plurality of cell fabrication machines to an assembly area for testing of a plurality of the cells and/or inserting of the cells into a nano-scale electric power generation module.

28. The system of claim 27, further comprising a module assembly device configured to selectively insert one or more cells into the nano-scale electric power generation module.

29. The system of claim 28, further comprising a system manufacturing device configured to selectively insert one or more of the nano-scale electric power generation modules into a nano-scale electric power generation system.

30. The system of claim 29, further comprising a control system configured to regulate operation of the plurality of cell fabrication machines, the cell transport device, the module assembly device, and the system manufacturing device.

31. The system of claim 1, wherein first device positioned proximal to the third dispenser is an electro-spray device, and the deposited fluid is a nano-fluid.

32. A system comprising:
a first dispenser configured to dispense a first component, the first component including:
a first electrode, the first electrode having a first work function value; and
a separation material positioned in at least partial communication with the first electrode;
a second dispenser configured to dispense a second component, the second component including a second electrode, the second electrode having a second work function value, the second work function value being different from the first work function value;
at least one device positioned proximal to the first dispenser, the device configured to deposit a fluid within at least a portion of the separation material dispensed from the first dispenser, at least a portion of particles within the fluid having a third work function value being different from the first and second work function values; and
a guide assembly operably coupled to the first and second dispensers, the guide assembly configured to transport the first and second components to a joint proximal position to form a fabricated product including the first and second components and the fluid.

33. The system of claim 32, wherein the second component further includes a casing material positioned in at least partial communication with the second electrode.

34. The system of claim 33, further comprising:
a first repository configured to provide the first component to the first dispenser for dispensing; and
a second repository configured to provide the second component form the second dispenser for dispensing, the first and second repositories being separately controlled repositories.

35. The system of claim 32, wherein the at least one device positioned proximal to the first dispenser is an electro-spray device, and the deposited fluid is a nano-fluid.

36. A system comprising:
a first dispenser configured to dispense a first material, the first material having a first work function value;
a second dispenser configured to dispense a second material, the second material having a second work function value, the second work function value being different from the first work function value;
a first device positioned proximal to the first dispenser, the first device configured to deposit at least one first electrospray material over at least a portion of the first material dispensed from the first dispenser to fabricate a first electrode material comprising the first material and the deposited first electrospray material, the fabricated first electrode material having a third work function value;
a second device positioned proximal to the second dispenser, the second device configured to deposit at least one second electrospray material over at least a portion of the second material dispensed from the second dispenser to fabricate a second electrode material comprising the second material and the deposited second electrospray material, the fabricated second electrode material having a fourth work function value;
a guide assembly operably coupled to the first and second dispensers, the guide assembly configured to transport the first and second electrode materials to a joint proximal position, including the guide assembly to position an opening between the first and second electrode materials;
a third dispenser configured to deposit a separation material into the positioned opening; and
the system configured to fabricate a product including the first and second electrode materials and the positioned separation material.

37. The system of claim 36, further comprising a vacuum chamber configured to infuse the fluid into the fabricated product, wherein:
the third work function value is less than the first work function value;
the fourth work function value is less than the second work function value, and the third work function value is less than the fourth work function value; and
the fluid having a fifth work function value greater than the third and fourth work function values, wherein the first and second electrode materials and the fluid cooperate to generate electric power as a function of the associated work functions.

38. The system of claim 37, wherein the first and second electrode materials and the positioned separation material at least partially define a first partial product, the system further comprising a transport device configured to selectively transport the first partial product from a first location to the vacuum chamber.

39. The system of claim 37, further comprising a fluid delivery system comprising:
at least one fluid reservoir; and
at least one fluid delivery conduit configured to couple the fluid reservoir in fluid communication with the vacuum chamber.

40. The system of claim 36, wherein first device positioned proximal to the first dispenser is a first electro-spray device, and the second device positioned proximal to the second dispense is a second electro-spray device.

41. The system of claim 37, wherein the fluid is a nano-fluid comprising a medium and a plurality of nano-particles.
